(19) United States
(12) Patent Application Publication
(10) Pub. No.: US 2012/0139070 A1
(43) Pub. Date: Jun. 7, 2012

(54) MANUFACTURING METHOD OF SEMICONDUCTOR DEVICE AND SEMICONDUCTOR DEVICE

(75) Inventor: Hiromichi KOBAYASHI, Kanagawa (JP)

(73) Assignee: RENESAS ELECTRONICS CORPORATION

(21) Appl. No.: 13/308,580

(22) Filed: Dec. 1, 2011

(30) Foreign Application Priority Data
Dec. 6, 2010 (JP) 2010-271447

(51) Int. Cl. H01L 31/0224

(52) U.S. Cl. 257/431; 438/98; 257/E31.124

(57) ABSTRACT

In a manufacturing method, the following regions are formed in a semiconductor substrate: a pixel region where a photoelectric conversion element is placed and a peripheral region placed in the peripheral portion of the pixel region. The following wiring and film are formed over the main surface of the semiconductor substrate: an uppermost-layer wiring and a first interlayer insulating film located over the uppermost-layer wiring. The uppermost surface of the first interlayer insulating film is flattened. After the step of flattening the uppermost surface, the uppermost surface of the first interlayer insulating film in the pixel region is flat; and a step is formed in the uppermost surface of the first interlayer insulating film in the peripheral region.

### CROSS-REFERENCE TO RELATED APPLICATIONS

The disclosure of Japanese Patent Application No. 2010-271447 filed on Dec. 6, 2010 including the specification, drawings and abstract is incorporated herein by reference in its entirety.

### BACKGROUND

The present invention relates to manufacturing methods of semiconductor devices and semiconductor devices and in particular to a manufacturing method of a semiconductor device including such a photoelectric conversion element as a photodiode and a semiconductor device manufactured by this manufacturing method.

In image sensors used in, especially, digital single-lens reflex cameras of digital cameras, a photodiode and the like as photoelectric conversion elements are usually covered from above with a laminated structure obtained by laminating an interlayer insulating film and the like.

It is desirable that the uppermost layer of this laminated structure should be flattened as much as possible. This is because any variation in the thickness of an entire laminated structure varies the amount of light absorption and interference colors of an image sensor. An imaging lens is installed over the uppermost layer of a laminated structure. When the plane on which the imaging lens is installed is flat, variation in the amount of light absorption or interference colors is suppressed and the reliability of the image sensor is enhanced. For example, Japanese Unexamined Patent Publication No. Hei 10 (1998)-294312 (hereafter, referred to as “Patent Document 1”) discloses a solid-state image sensing device. In this image sensing device, the uppermost surface of an insulating film formed over an element portion made up of a photoreceptor portion and a gate electrode by a CVD (Chemical Vapor Deposition) method is flattened.

In an area where a metal wiring of aluminum or the like is formed, a step due to the thickness of the metal wiring is formed. For this reason, a step is formed in the uppermost surface of a laminated structure obtained by laminating an interlayer insulating film and the like over a metal wiring and this often degrades the flatness thereof. For example, Japanese Unexamined Patent Publication No. Hei 4 (1992)-188733 (hereafter, referred to as “Patent Document 2”) describes the following: when a metal wiring is wide in the horizontal direction, a protrusion is produced on the uppermost surface of an insulating film laminated over the metal wiring by a CVD method and this degrades the flatness of this uppermost surface. Japanese Unexamined Patent Publication No. 2004-179571 (hereafter, referred to as “Patent Document 3”) describes that the following takes place when the thickness of an insulating film laminated over a pattern of a silicon nitride film by an HDP (High Density Plasma)-CVD method is increased: a protrusion on the uppermost surface of the insulating film over the pattern is reduced in size and the uppermost surface of the insulating film is further flattened.

[Patent Document 1]
Japanese Unexamined Patent Publication No. Hei 10 (1998)-294312

[Patent Document 2]
Japanese Unexamined Patent Publication No. Hei 4 (1992)-188733

[Patent Document 3]
Japanese Unexamined Patent Publication No. 2004-179571

### SUMMARY

As described in Patent Document 3, the flatness of the uppermost surface of an interlayer insulating film forming the uppermost layer of a laminated structure is more enhanced with increase in the thickness of the interlayer insulating film. However, when the formed laminated structure becomes excessively thick, there is a possibility that light is diverged in the horizontal direction when it is used as an image sensor and this degrades the characteristics thereof. Therefore, a thinner formed laminated structure is more desirable. To reduce the thickness of a laminated structure and enhance the flatness of the uppermost surface of the laminated structure, for example, the following procedure is taken: over a metal wiring, as thick an interlayer insulating film as possible (for example, one having a thickness approximately three times the thickness of the metal wiring) is formed; and thereafter, a certain thickness is removed from the uppermost surface of the interlayer insulating film by a chemical-mechanical polishing method designated as CMP (Chemical Mechanical Polishing).

In the above method, the formed interlayer insulating film is very thick and the interlayer insulating film is removed by a considerable thickness by CMP. This can incur increase in cost. None of Patent Document 1 to Patent Document 3 describes a configuration with all of the following taken into account: the above processing cost, the flatness of the uppermost surface, and the overall thickness of a formed laminated structure.

The invention has been made in consideration of the above problem. It is an object thereof to provide a manufacturing method of a semiconductor device in which a cost can be reduced, excellent flatness can be achieved, and an entire laminated structure can be formed as thin as possible. It is another object thereof to provide a semiconductor device manufactured using this manufacturing method.

A manufacturing method of a semiconductor device in an example of the invention includes the steps described below. First, the following regions are formed in a semiconductor substrate having a main surface: a pixel region where a photoelectric conversion element is placed and a peripheral region placed in the peripheral portion of the pixel region with respect to the direction along the main surface. At least one layer of a metal wiring is formed over the main surface of the semiconductor substrate. A first interlayer insulating film is formed over the uppermost-layer wiring farthest from the semiconductor substrate among the metal wirings. The uppermost surface of the first interlayer insulating film is flattened. The width along the main surface of the uppermost-layer wiring in the peripheral region is larger than the width of the uppermost-layer wiring in the pixel region. At the step of forming the first interlayer insulating film, the thickness T, in the direction orthogonal to the main surface, of the first interlayer insulating film formed in an area where it does not overlap with the uppermost-layer wiring as viewed in a plane satisfies the following relation: the relation of T≧H+W/4, where W is the length of the diagonal lines of each intersecting portion of the uppermost-layer wiring placed in the pixel region; and H is the height of the uppermost-layer wiring placed in the pixel region in the direction orthogonal to the main surface. After the above-mentioned flattening step is carried out, the uppermost surface of the first interlayer insulating film in the pixel region is flat and a step is formed in the uppermost surface of the first interlayer insulating film in the peripheral region.

A manufacturing method of a semiconductor device in another example of the invention includes the steps describe below. First, the following regions are formed in a semiconductor substrate having a main surface: a pixel region where a photoelectric conversion element is placed and a peripheral region placed in the peripheral portion of the pixel region with respect to the direction along the main surface. At least one layer of a metal wiring is formed over the main surface of the semiconductor substrate. A first interlayer insulating film is formed over the uppermost-layer wiring farthest from the semiconductor substrate among the metal wirings. The width along the main surface of the uppermost-layer wiring in the peripheral region is larger than the width of the uppermost-layer wiring in the pixel region. At the step of forming the first interlayer insulating film, the thickness T, in the direction orthogonal to the main surface, of the first interlayer insulating film formed in an area where it does not overlap with the uppermost-layer wiring as viewed in a plane satisfies the following relation: the relation of T≧H+W/2, where W is the length of the diagonal lines of the intersecting portion of the uppermost-layer wiring placed in the pixel region; and H is the height of the uppermost-layer wiring placed in the pixel region in the direction orthogonal to the main surface. After the step of forming the first interlayer insulating film is carried out, the uppermost surface of the first interlayer insulating film in the pixel region is flat and a step is formed in the uppermost surface of the first interlayer insulating film in the peripheral region.

A semiconductor device in another example of the invention has the configuration described below. The semiconductor device includes: a semiconductor substrate having a main surface; a pixel region formed in the semiconductor substrate where a photoelectric conversion element is placed; and a peripheral region placed in the peripheral portion of the pixel region with respect to the direction along the main surface. In the pixel region and the peripheral region, there are provided: at least one layer of a metal wiring formed over the semiconductor substrate; and a first interlayer insulating film formed over the uppermost-layer wiring farthest from the semiconductor substrate among the metal wirings. The uppermost surface of the first interlayer insulating film in the pixel region is flat and a step is formed in the uppermost surface of the first interlayer insulating film in the peripheral region.

According to a manufacturing method in an example of the invention, the following can be implemented by forming a first interlayer insulating film whose thickness is H+W/4 or above over the uppermost-layer wiring: the uppermost surface of the interlayer insulating film at least in the pixel region can be flattened by subsequent flattening processing on the interlayer insulating film. For this reason, a semiconductor device having a highly functional photoelectric conversion element can be provided by a smaller amount of processing (cost).

According to a manufacturing method in another example of the invention, the following can be implemented by forming a first interlayer insulating film whose thickness is H+W/2 or above over the uppermost-layer wiring: the uppermost surface of the interlayer insulating film at least in the pixel region can be flattened without thereafter carrying out flattening processing on the interlayer insulating film. For this reason, a semiconductor device having a highly functional photoelectric conversion element can be provided by a smaller amount of processing (cost).

In another example of the invention, the uppermost surface of the first interlayer insulating film at least in the pixel region is flat. For this reason, the minimum high functionality of a photoelectric conversion element is ensured even though there is a step in the uppermost surface of the first interlayer insulating film in the peripheral region.

### BRIEF DESCRIPTION OF THE DRAWINGS

FIG. 1 is a schematic plan view illustrating the state of a wafer of a semiconductor device in a first embodiment;

FIG. 2 is a schematic enlarged plan view of the area encircled with a broken line “II” in FIG. 1;

FIG. 3 is a schematic enlarged plan view illustrating the state of a chip corresponding to the area encircled with a broken line “III” in FIG. 2;

FIG. 4 is a schematic sectional view illustrating the configuration of a semiconductor device in the first embodiment;

FIG. 5 is a schematic sectional view illustrating the configuration of the uppermost-layer wiring;

FIG. 6 is a schematic plan view of an area where the photodiode in FIG. 4 is arranged in multiple rows;

FIG. 7 is a schematic sectional view illustrating the configuration of a conductive layer coupling metal wirings together;

FIG. 8 is a schematic sectional view illustrating a first step of a manufacturing method of a semiconductor device in the first embodiment of the invention;

FIG. 9 is a schematic sectional view illustrating a second step of the manufacturing method of the semiconductor device in the first embodiment of the invention;

FIG. 10 is a schematic sectional view illustrating a third step of the manufacturing method of the semiconductor device in the first embodiment of the invention;

FIG. 11 is a schematic sectional view illustrating a fourth step of the manufacturing method of the semiconductor device in the first embodiment of the invention;

FIG. 12 is a schematic sectional view illustrating a fifth step of the manufacturing method of the semiconductor device in the first embodiment of the invention;

FIG. 13 is a schematic sectional view illustrating a sixth step of the manufacturing method of the semiconductor device in the first embodiment of the invention;

FIG. 14 is a schematic sectional view illustrating a seventh step of the manufacturing method of the semiconductor device in the first embodiment of the invention;

FIG. 15 is a schematic sectional view illustrating an eighth step of the manufacturing method of the semiconductor device in the first embodiment of the invention;

FIG. 16 is a schematic sectional view illustrating a ninth step of the manufacturing method of the semiconductor device in the first embodiment of the invention;

FIG. 17 is a schematic sectional view illustrating a 10th step of the manufacturing method of the semiconductor device in the first embodiment of the invention;

FIG. 18 is a schematic sectional view illustrating an 11th step of the manufacturing method of the semiconductor device in the first embodiment of the invention;

FIG. 19 is a schematic sectional view illustrating a 12th step of the manufacturing method of the semiconductor device in the first embodiment of the invention;

FIG. 20 is a schematic sectional view illustrating a 13th step of the manufacturing method of the semiconductor device in the first embodiment of the invention;

FIG. 21 is a schematic sectional view illustrating a 14th step of the manufacturing method of the semiconductor device in the first embodiment of the invention;

FIG. 22 is a schematic sectional view illustrating a 15th step of the manufacturing method of the semiconductor device in the first embodiment of the invention;

FIG. 23 is a schematic sectional view illustrating the relation between the width of a metal wiring and the shape of an interlayer insulating film thereover in the first embodiment;

FIG. 24 is a schematic sectional view illustrating the configuration of a semiconductor device in a comparative example of the invention;

FIG. 25 is a schematic sectional view of the step, equivalent to that in FIG. 18, of a manufacturing method of the semiconductor device in the comparative example illustrated in FIG. 24;

FIG. 26 is a schematic sectional view illustrating the step, following that in FIG. 25, of the manufacturing method of the semiconductor device in the comparative example illustrated in FIG. 24;

FIG. 27 is a schematic sectional view illustrating the step, following that in FIG. 26, of the manufacturing method of the semiconductor device in the comparative example illustrated in FIG. 24;

FIG. 28 is a schematic sectional view illustrating the configuration of a semiconductor device in a second embodiment;

FIG. 29 is a schematic sectional view illustrating the step, equivalent to that in FIG. 18, of a manufacturing method of the semiconductor device in the second embodiment of the invention;

FIG. 30 is a schematic sectional view illustrating the relation between the width of a metal wiring and the shape of an interlayer insulating film thereover in the second embodiment;

FIG. 31 is a schematic sectional view illustrating the step, following that in FIG. 18, of a manufacturing method of the semiconductor device in a third embodiment of the invention;

FIG. 32 is a schematic sectional view illustrating the configuration of a semiconductor device in the third embodiment;

FIG. 33 is a schematic sectional view illustrating the step, following that in FIG. 18, of a manufacturing method of the semiconductor device in a fourth embodiment of the invention;

FIG. 34 is a schematic sectional view illustrating the configuration of a semiconductor device in the fourth embodiment;

FIG. 35 is a schematic sectional view illustrating the step, following that in FIG. 18, of a manufacturing method of the semiconductor device in a fifth embodiment of the invention;

FIG. 36 is a schematic sectional view illustrating the configuration of a semiconductor device in the fifth embodiment;

FIG. 37 is a schematic sectional view illustrating the step, following that in FIG. 16, of a manufacturing method of the semiconductor device in a sixth embodiment of the invention; and

FIG. 38 is a schematic sectional view illustrating the configuration of a semiconductor device in the sixth embodiment.

### DETAILED DESCRIPTION

Hereafter, description will be given to embodiments of the invention with reference to the drawings.

### First Embodiment

First, description will be given to a semiconductor device in the state of wafer in this embodiment.

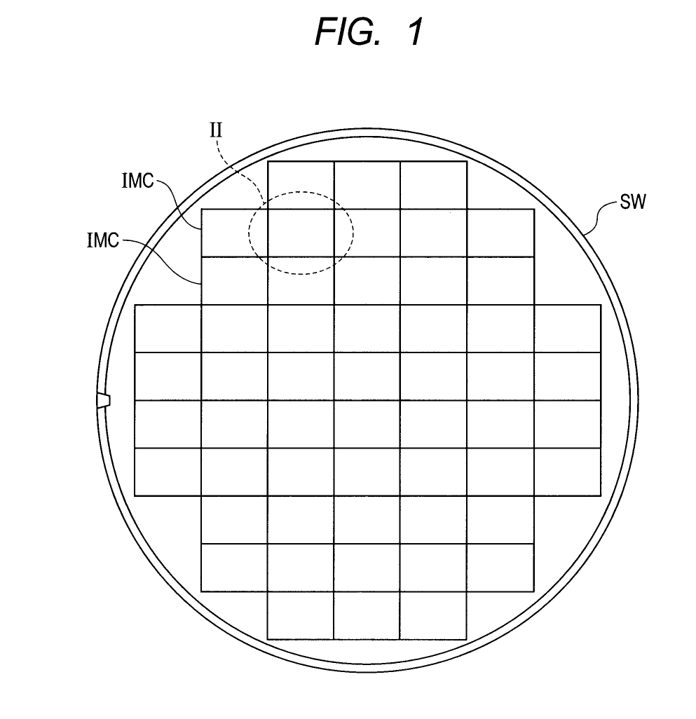

As illustrated in FIG. 1, multiple chip areas IMC for image sensor are formed in a semiconductor wafer SW. Each of the chip areas IMC has a rectangular planar shape and they are arranged in a matrix pattern.

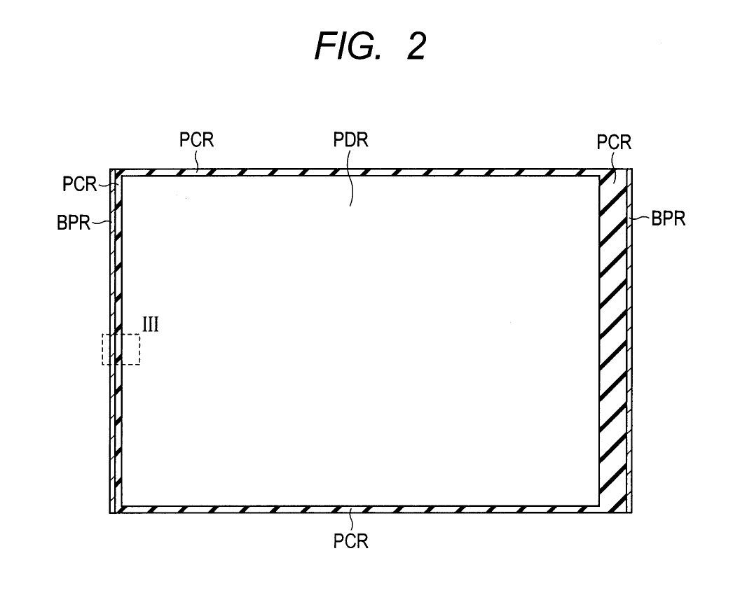

As illustrated in FIG. 2, each of the chip areas IMC includes a pixel region PDR where, for example, a photodiode is formed and a peripheral region PCR where a peripheral circuit for controlling the photodiode is formed. The peripheral region PCR is formed in, for example, the periphery of the pixel region PDR and it is an area for blocking off light applied to a photoelectric conversion element formed in the pixel region PDR. A bonding pad region BPR is provided, for example, on both sides of an area including the peripheral region PCR and the pixel region PDR. The bonding pad region BPR is a region where multiple bonding pads for inputting/outputting signals between a photodiode in the pixel region PDR and an external circuit are arranged at intervals. It is desirable that a dicing line region for cutting each chip area IMC from the semiconductor wafer SW should be formed in the edge portion (peripheral region PCR or bonding pad region BPR) of each chip area IMC.

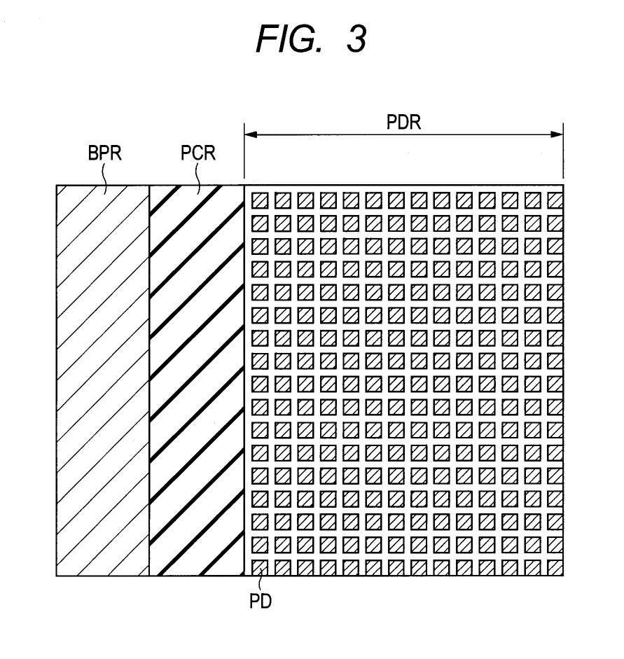

As an example, each chip area IMC illustrated in FIG. 2 is 20 mm in length in the vertical direction and 30 mm in length in the horizontal direction. The width of the peripheral region PCR on the left side of FIG. 2 is 0.1 mm; the width of the right peripheral region PCR is 1.5 mm; the width of the upper peripheral region PCR is 0.05 mm; and the width of the lower peripheral region PCR is 0.2 mm. The width of the bonding pad region BPR both on the left side and on the right side is 0.1 mm. As illustrated in FIG. 3, a large number of photodiode PDs (photoelectric conversion elements) are arranged in the pixel region PDR.

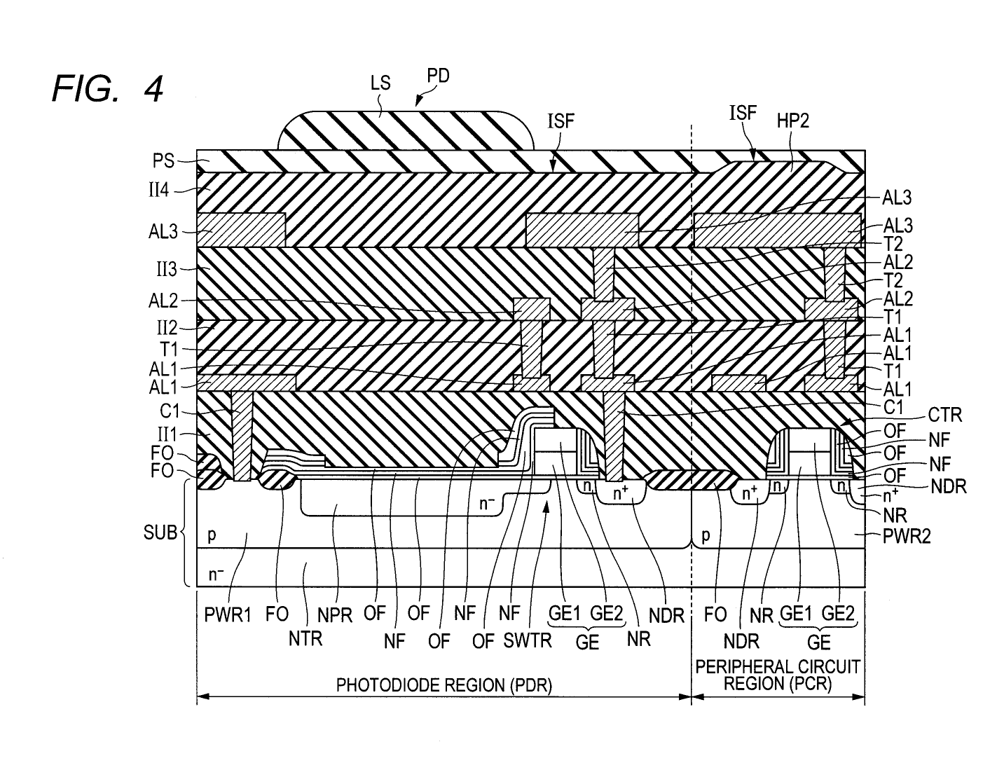

FIG. 4 illustrates a photodiode PD in the area in the pixel region PDR in FIG. 3 closest to the peripheral region PCR and the peripheral circuit in the peripheral region PCR so that they are juxtaposed to each other. With respect to the image sensor in this embodiment, as illustrated in FIG. 4, multiple photodiodes PD configured as illustrated in FIG. 4 are arranged in the photodiode region (pixel region PDR). Multiple peripheral circuits CTR configured as illustrated in FIG. 4 are arranged in the peripheral circuit region (peripheral region PCR).

More specific description will be given. The image sensor is formed in a n⁻-region NTR of a semiconductor substrate SUB comprised of, for example, silicon. Each photodiode PD and each peripheral circuit CTR are separated from each other as viewed in a plane by a field oxide film FO formed in the surface of the semiconductor substrate SUB.

The photodiode PD is made up of a p-type well region PWR1 and an n-type impurity region NPR. The p-type well region PWR1 is formed in the surface of the semiconductor substrate SUB in the photodiode region PDR. The n-type impurity region NPR is formed in the surface of the semiconductor substrate SUB in the p-type well region PWR1 and forms a p-n junction together with the p-type well region PWR1. In FIG. 4, the reference code PD of photodiode is placed above a condenser lens LS (imaging lens) to clarify the position of the photodiode PD as viewed in a plane. However, it is the area where the p-type well region PWR1 and the n-type impurity region NPR are in contact with each other that forms the p-n junction that carries out the main functions of the photodiode PD.

In the photodiode region, a MIS (Metal Insulator Semiconductor) transistor, such as a transfer transistor SWTR, is also formed. Especially, the transfer transistor SWTR includes a pair of source/drain regions NPR and NR, NDR, a gate insulating film, and a gate electrode GE. In this example, the gate insulating film of the transfer transistor SWTR is obtained, for example, by extending a silicon oxide film OF so formed as to cover the photodiode PD. The pair of n-type source/drain regions NPR and NR, NDR are placed over the surface of the semiconductor substrate SUB in the p-type well region PWR1 at a distance from each other. One region NPR of the pair of n-type source/drain regions NPR and NR, NDR is integrated with the n-type impurity region NPR of the photodiode PD and they are electrically coupled with each other. The other region NR, NDR of the pair of source/drain regions NPR and NR, NDR includes a n⁺-impurity region NDR as a high-concentration region and an n-type impurity region NR as LDD (Lightly Doped Drain). The gate electrode GE is formed over the surface of the semiconductor substrate SUB sandwiched between the pair of source/drain regions NPR and NR, NDR with the gate insulating film in between.

In the area on the left side of the photodiode PD in FIG. 4, the surface of the semiconductor substrate SUB in the p-type well region PWR1 is coupled with an upper-layer wiring. For this reason, positive electric charges produced when light is applied to the photodiode PD can migrate toward the upper-layer wiring.

An antireflection film comprised of a laminated structure of the silicon oxide film OF and a silicon nitride film NF is formed over the surface of the semiconductor substrate SUB so as to cover the photodiode PD. One end of this antireflection film OF, NF runs on to the gate electrode GE on one side. As the residue of the antireflection film OF, NF, a side wall insulating layer made up of the silicon oxide film OF and the silicon nitride film NF is formed over the side wall of the gate electrode GE on the other side.

For example, a p-type well region PWR2 is formed in the surface of the semiconductor substrate SUB in the peripheral circuit region. In this p-type well region PWR2, there is formed a controlling element for controlling the operations of multiple photodiodes PD and this controlling element includes, for example, a MIS transistor CTR.

The MIS transistor CTR includes a pair of n-type source/drain regions NR, NDR, a silicon oxide film OF as a gate insulating film, and a gate electrode GE. The pair of n-type source/drain regions NR, NDR are formed in the surface of the semiconductor substrate SUB at a distance from each other. Each of the pair of n-type source/drain regions NR, NDR includes, for example, an n-type impurity region NDR as a high-concentration region and an n-type impurity region NR as LDD.

The gate electrode GE is formed over the surface of the semiconductor substrate SUB sandwiched between the pair of n-type source/drain regions NR, NDR with the gate insulating film in between. As the residue of the antireflection film, a side wall insulating layer made up of an oxide film OF and a nitride film NF is formed over the side wall of the gate electrode GE.

It is desirable that the gate electrodes GE of each MIS transistor in the photodiode region and the peripheral circuit region should be configured by: laminating an insulating layer GE2 comprised of, for example, TEOS (Tetraethoxysilane) over a polycrystalline layer GE1 comprised of polycrystalline silicon doped with an impurity. Or, it may be formed of, for example, a metal such as titanium nitride (TiN).

An interlayer insulating film II1 is formed over the surface of the semiconductor substrate SUB so as to cover the above elements (photodiode PD, MIS transistors SWTR, CTR) in each of the photodiode region and the peripheral circuit region (dicing line region). In the photodiode region and the peripheral circuit region, a patterned first-layer metal wiring AL1 is formed over the interlayer insulating film II1. This first-layer metal wiring AL1 is electrically coupled to, for example, a p⁺-impurity region PDR or a n⁺-impurity region NDR through a conductive layer C1 filled in contact holes in the interlayer insulating film M.

In the peripheral circuit region, a stopper film AL1 is formed over the interlayer insulating film II1. This stopper film AL1 is formed separately from the same metal film as the metal wiring AL1 by, for example, ordinary photoengraving process and etching process.

An interlayer insulating film II2 is formed over the interlayer insulating film II1 so as to cover the metal wiring AL1 and the stopper film AL1 from above. In the photodiode region and the peripheral circuit region, a patterned second-layer metal wiring AL2 is formed over the interlayer insulating film II2. The second-layer metal wiring AL2 is electrically coupled with the first-layer metal wiring AL1 through a conductive layer T1 filled in through holes in the interlayer insulating film II2.

An interlayer insulating film II3 is formed over the interlayer insulating film II2 so as to cover the metal wiring AL2. In the photodiode region and the peripheral circuit region, a patterned third-layer metal wiring AL3 is formed over the interlayer insulating film II3. The third-layer metal wiring AL3 is electrically coupled with the second-layer metal wiring AL2 through a conductive layer T2 filled in through holes in the interlayer insulating film II3.

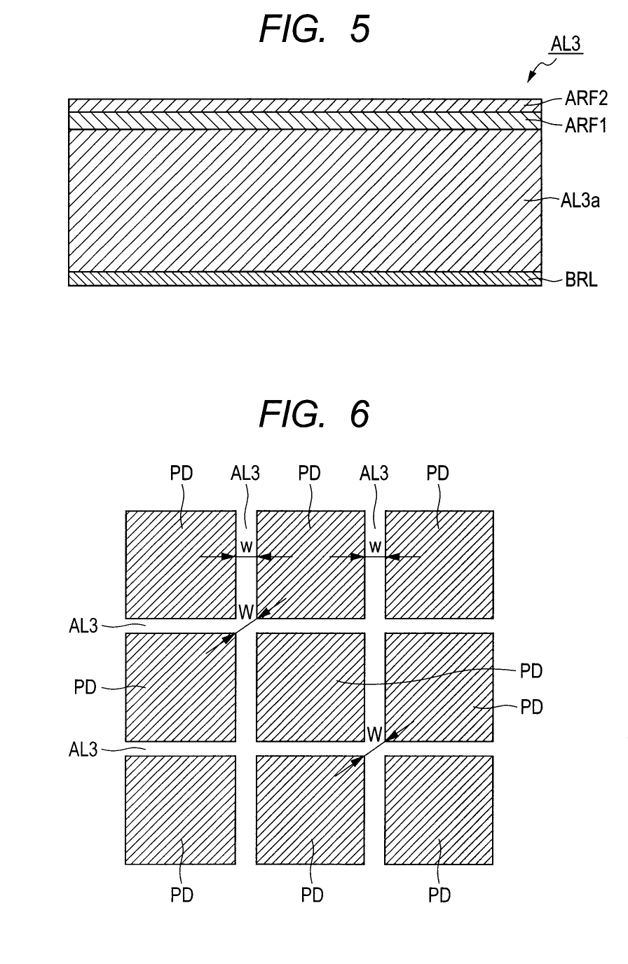

In the semiconductor device in FIG. 4, the metal wiring AL3 is the uppermost-layer wiring farthest from the semiconductor substrate. It is desirable that the metal wiring AL3 should be configured, for example, by laminating a barrier layer BRL, a metal layer AL3a, an antireflection film ARF1, and an antireflection film ARF2 as illustrated in FIG. 5. In this embodiment, for example, a thin film of titanium nitride is adopted as the barrier layer BRL and, for example, aluminum (Al) is adopted for the metal layer AL3a. For example, a thin film of titanium nitride is adopted as the antireflection film ARF1 and, for example, a thin film of titanium is adopted as the antireflection film ARF2. It is desirable that the metal wiring AL3 in the photodiode region PDR should also be configured similarly to the metal wiring AL3 in the peripheral circuit region PCR. The metal wirings AL1, AL2 may also have the same laminated structure (in which an antireflection film is formed) as the metal wiring AL3.

An interlayer insulating film II4 (first interlayer insulating film) is formed over the interlayer insulating film II3 so as to cover the metal wiring AL3. A passivation film PS is formed over this interlayer insulating film II4. The condenser lens LS is placed over this passivation film PS directly above the photodiode PD. This condenser lens LS is for collecting light and applying it to the photodiode PD.

In the photodiode region PDR, as illustrated in FIG. 6, the metal wiring AL3 is formed in the areas sandwiched between multiple photodiodes PD arranged at intervals as viewed in a plane. The width w in the direction orthogonal to the direction in which the metal wiring AL3 is extended is substantially equal to the distance between adjoining photodiodes PD. When all the parts of the metal wiring AL3 in FIG. 6 are substantially equal in width w, the length W of the diagonal lines of each intersecting portion of the metal wiring AL3 is substantially √2 times w. This is because all the parts of the metal wiring AL3 are substantially equal in width w and thus the intersecting portions (overlapped portions) of any two parts of the metal wiring AL3 intersecting with (for example, orthogonal to) each other are square. That is, the length W of the diagonal lines of each intersecting portion of the metal wiring AL3, cited here, refers to the following length: the length of the diagonal lines (in the oblique directions in FIG. 6) of the quadrangle (square) formed by each intersecting portion of two parts of the metal wiring AL3.

In the peripheral circuit region PCR, meanwhile, the metal wiring AL3 is so formed as to cover substantially the entire surface. The metal wiring AL3 blocks off light coming from above and suppresses light coming from any area other than the condenser lens LS from arriving at the photodiode PD located therebelow. When substantially the entire surface of the peripheral circuit region PCR is covered with the metal wiring AL3, the above-mentioned light blocking effect can be further enhanced. Therefore, it is desirable to take the measure illustrated in FIG. 4. That is, it is desirable to make the following width larger than the width of each part of the metal wiring AL3 in the photodiode region PDR: the width of the metal wiring AL3 in the peripheral circuit region PCR along the main surface of the semiconductor substrate SUB (in the horizontal direction in FIG. 4).

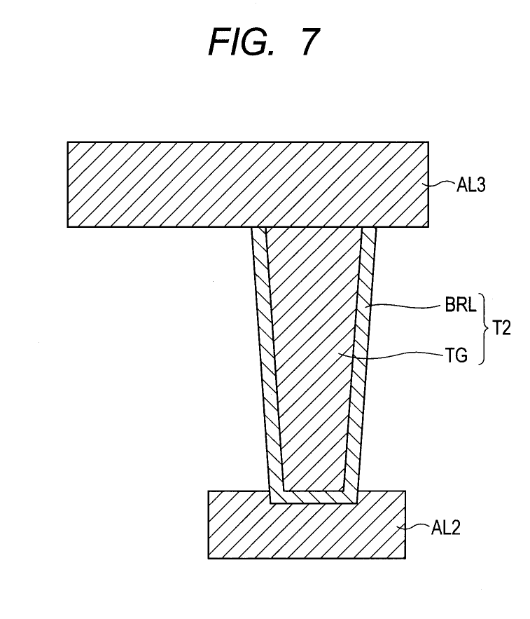

As illustrated in FIG. 7, it is desirable that the conductive layer T2 that penetrates the interlayer insulating film II3 and couples together the metal wiring AL3 and the metal wiring AL2 should be configured as follows: the outer wall portion thereof is covered with a barrier layer BRL made up of a thin film of, for example, titanium nitride and the interior thereof is filled with metal material TG, such as tungsten. The conductive layers T1, C1 may also be configured similarly to the conductive layer T2.

In the above example, the interlayer insulating films II1, II2, II3, II4 are made up of, for example, a silicon oxide film and formed of a material different in etching selectivity from those of the metal wirings AL1, AL2, AL3. (The etching selectivity is etching selectivity used, for example, when the interlayer insulating films II2, II3 are etched to form through holes for the conductive layers T1, T2.) Each of the interlayer insulating films II1, II2, II3, II4 is continuous and integral between the photodiode region PDR and the peripheral circuit region PCR. The uppermost surface ISF of the interlayer insulating film II4 in the photodiode region PDR is flat and a step is formed in the uppermost surface ISF of the interlayer insulating film II4 in the peripheral circuit region PCR.

Specific description will be given. As illustrated in FIG. 4, the uppermost surface ISF of the interlayer insulating film II4 in the photodiode region PDR is similarly flat both in areas where it covers the metal wiring AL3 and in areas where it does not cover the metal wiring AL3. In the photodiode region PDR, any conspicuous step is not formed in the uppermost surface ISF of the interlayer insulating film II4. Meanwhile, the interlayer insulating film II4 in the peripheral circuit region PCR has a step formed in the uppermost surface ISF thereof. That is, over the metal wiring AL3 in the peripheral circuit region PCR, the insulating film surface ISF is in a more swelled shape than in other areas as shown in the upper part of FIG. 4 and an insulating film step HP2 is formed.

More specific description will be given. That the uppermost surface ISF of the interlayer insulating film II4 in the photodiode region PDR is flat refers to the following state: a state in which the following difference is 25% or less of the width W (length of the diagonal lines of each intersecting portion) of the metal wiring AL3: the difference between the maximum value and the minimum value of the distance between the insulating film surface ISF in the photodiode region PDR and the main surface of the semiconductor substrate SUB in the direction of thickness. Conversely, that there is a step in the uppermost surface ISF of the interlayer insulating film II4 in the photodiode region PDR refers to the following state: a state in which the following difference is larger than 25% of the width W (length of the diagonal lines of each intersecting portion) of the metal wiring AL3: the difference between the maximum value and the minimum value of the above distance of the insulating film surface ISF in the photodiode region PDR. This definition also applies to the insulating film surface ISF in the peripheral circuit region PCR. It is desirable that the measurement values of the flatness and step should be obtained using a stylus profilometer, an AFM (Atomic Force Microscope) step measuring instrument, and a cross section SEM (Scanning Electron Microscope).

In this embodiment, the insulating film surface ISF of the interlayer insulating film II4 is flat in the photodiode region PDR but it is not flat in the peripheral circuit region PCR. The present inventors devoted themselves to studies and found the following. The photoelectric conversion elements such as the photodiode PD are formed in the photodiode region PDR. Therefore, the following can be implemented as long as the uppermost surface ISF of the interlayer insulating film II4 in the photodiode region PDR is flat as illustrated in FIG. 4: even if the flatness of the uppermost surface ISF of the interlayer insulating film II4 in the peripheral circuit region PCR is degraded, it is possible to ensure the high functionality and quality of the photodiode PD.

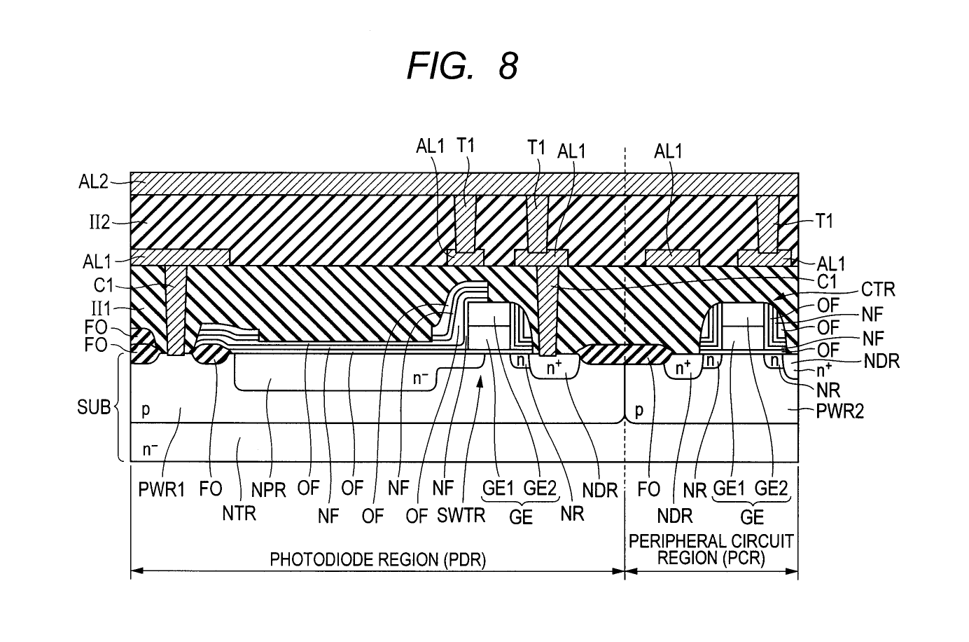

Description will be given to a manufacturing method of the semiconductor device in this embodiment illustrated in FIG. 4 with reference to FIG. 8 to FIG. 23. The configuration of the interlayer insulating film II2 and the lower layers is formed by a publicly known method using a semiconductor substrate SUB formed of different semiconductor materials, such as silicon and germanium, according to the wavelength of light applied when it is used. Therefore, the description thereof will be omitted here.

As illustrated in FIG. 8, the thin film AL2 formed of, for example, aluminum is formed over the interlayer insulating film II2 in which the conductive layer T1 is formed by, for example, sputtering. It is formed both in the photodiode region PDR and in the peripheral circuit region PCR. However, the thin film AL2 may include the barrier layer BRL and the antireflection films ARF1, ARF2 as illustrated in FIG. 5.

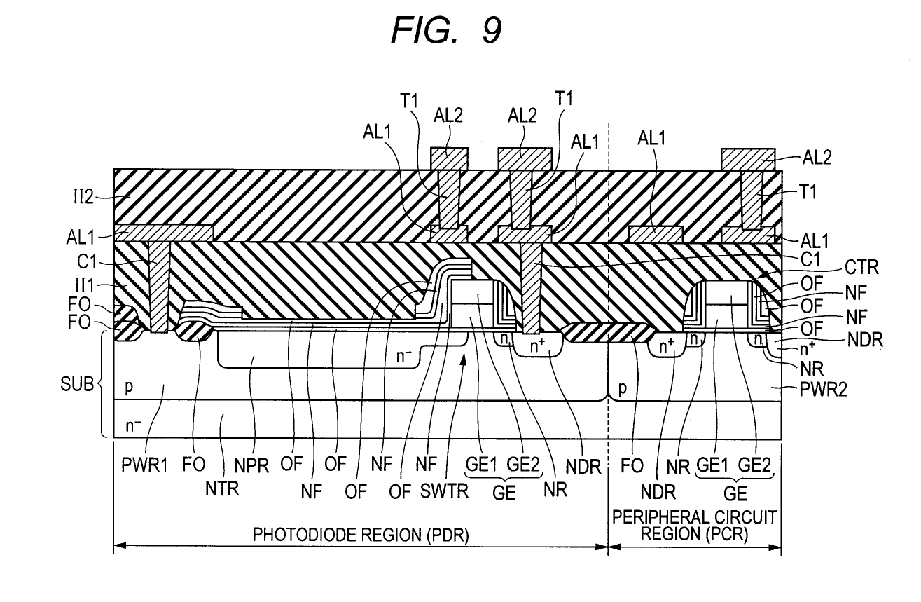

As illustrated in FIG. 9, the metal wiring AL2 formed of, for example, aluminum is formed by ordinary photoengraving process and etching process both in the photodiode region PDR and in the peripheral circuit region PCR. However, the metal wiring AL2 may include the barrier layer BRL and the antireflection films ARF1, ARF2 as illustrated in FIG. 5. The metal wiring AL2 in the photodiode region PDR and the peripheral circuit region PCR is so formed that it is electrically coupled to the metal wiring AL1 through the conductive layer T1. The metal wiring AL1 is electrically coupled to the n-type region NDR and the like in the surface of the semiconductor substrate SUB.

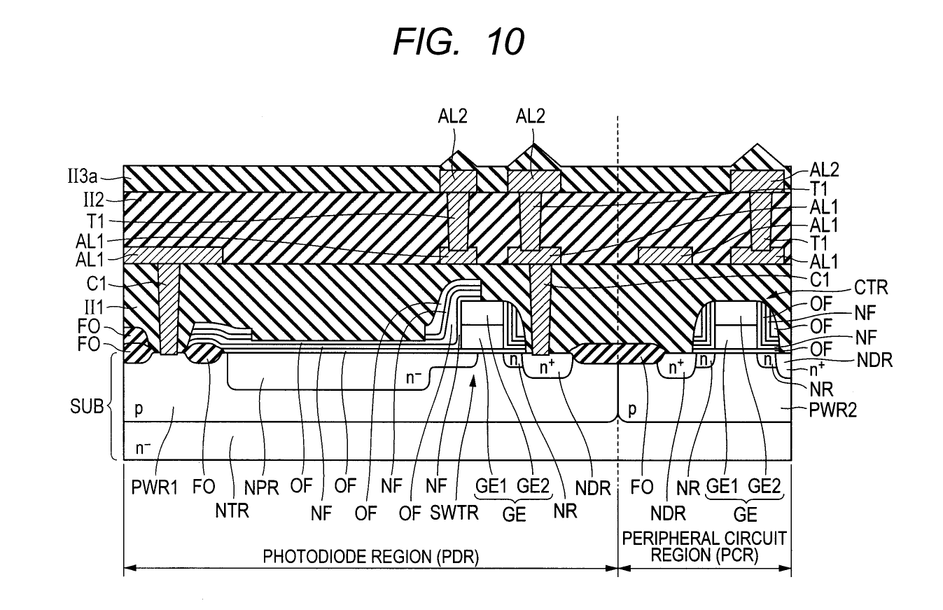

As illustrated in FIG. 10, the interlayer insulating film II3a is formed over the interlayer insulating film II2 and the metal wiring AL2 by, for example, an HDP-CVD method both in the photodiode region PDR and in the peripheral circuit region PCR. The cross-sectional shape of the interlayer insulating film II3a formed at this time is a triangular shape with the top pointed, especially, over the areas turned into a step due to the metal wiring AL2.

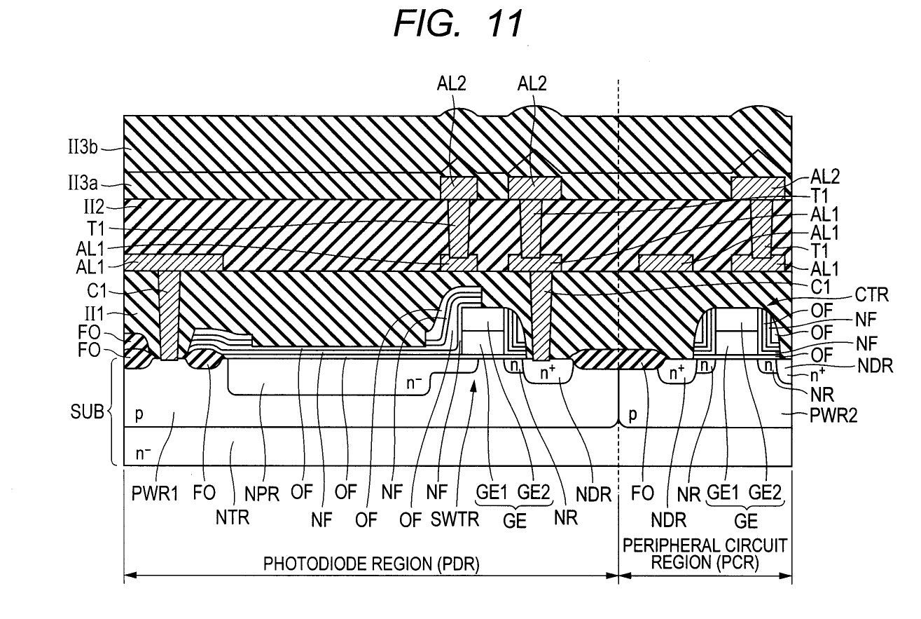

As illustrated in FIG. 11, the interlayer insulating film II3b is formed over the interlayer insulating film II3a by, for example, a plasma CVD method both in the photodiode region PDR and in the peripheral circuit region PCR.

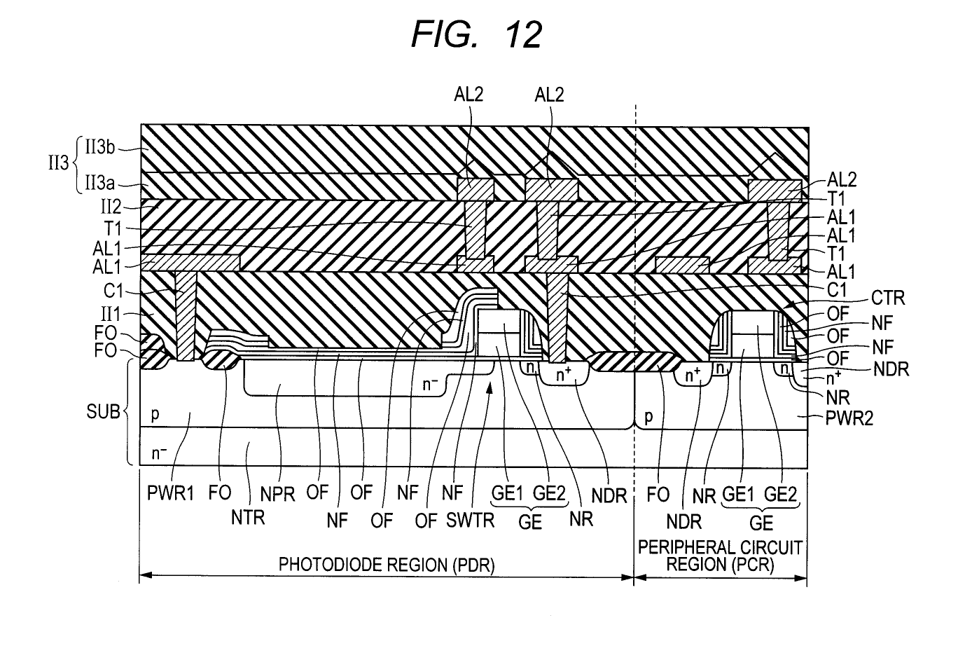

As illustrated in FIG. 12, an area equivalent to a certain thickness is polished and removed from the uppermost surface of the interlayer insulating film II3b by, for example, CMP both in the photodiode region PDR and in the peripheral circuit region PCR. The uppermost surface of the interlayer insulating film II3b is thereby flattened. Since the interlayer insulating film II3a and the interlayer insulating film II3b are both a silicon oxide film in this example, they are combined to form the interlayer insulating film II3 made up of the silicon oxide films.

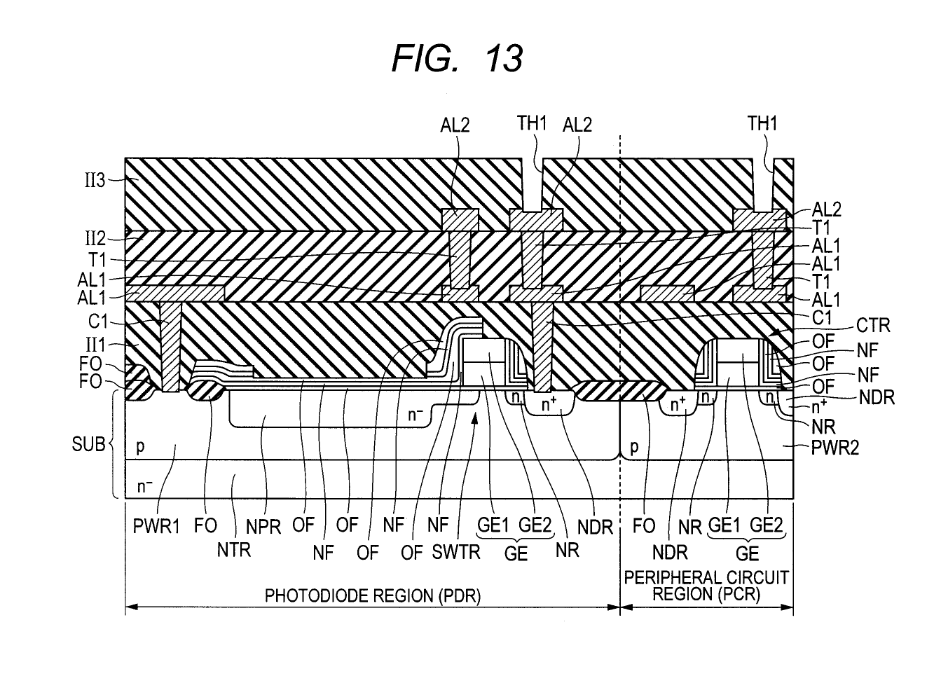

As illustrated in FIG. 13, parts of the interlayer insulating film II3, especially, over the metal wiring AL2 are removed by ordinary photoengraving process and etching process both in the photodiode region PDR and in the peripheral circuit region PCR. They are removed so that through holes TH1 extended from the uppermost surface of the interlayer insulating film II3 to the metal wiring AL2 are formed.

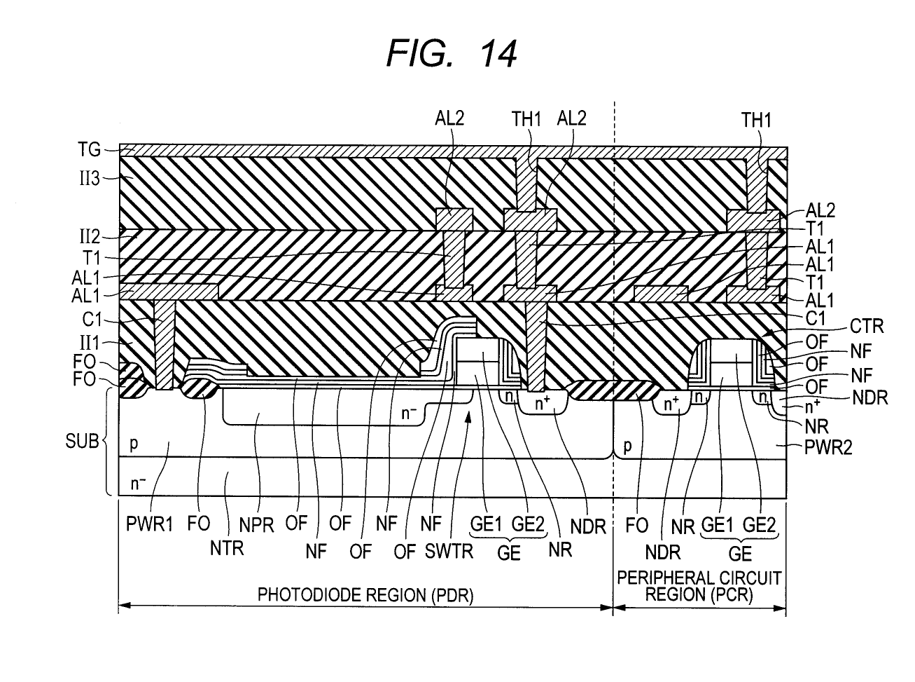

As illustrated in FIG. 14, the interior of each through hole TH1 is filled with tungsten TG by, for example, sputtering both in the photodiode region PDR and in the peripheral circuit region PCR. A thin film of tungsten is formed over the interlayer insulating film II3 as well as in the interior of each through hole TH1 by this sputtering. Before filling tungsten, a thin film of titanium nitride may be formed as the barrier layer BRL (Refer to FIG. 7) on the inner wall surface of each through hole TH1 by, for example, sputtering.

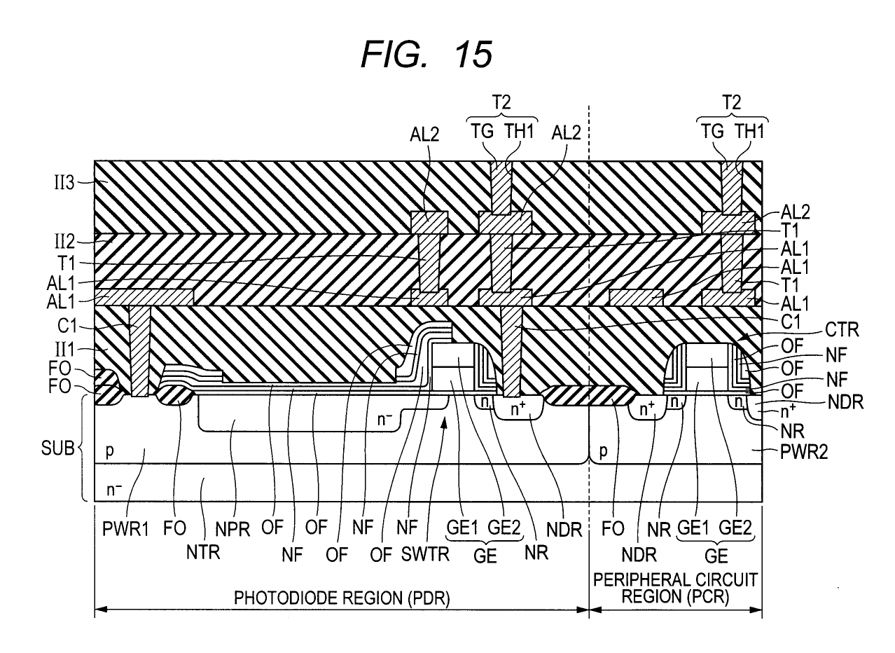

As illustrated in FIG. 15, the thin film TG of tungsten formed over the interlayer insulating film II3 is polished and removed by, for example, CMP both in the photodiode region PDR and in the peripheral circuit region PCR. At this time, the conductive layer T2 is formed by tungsten TG filled in the through holes TH1.

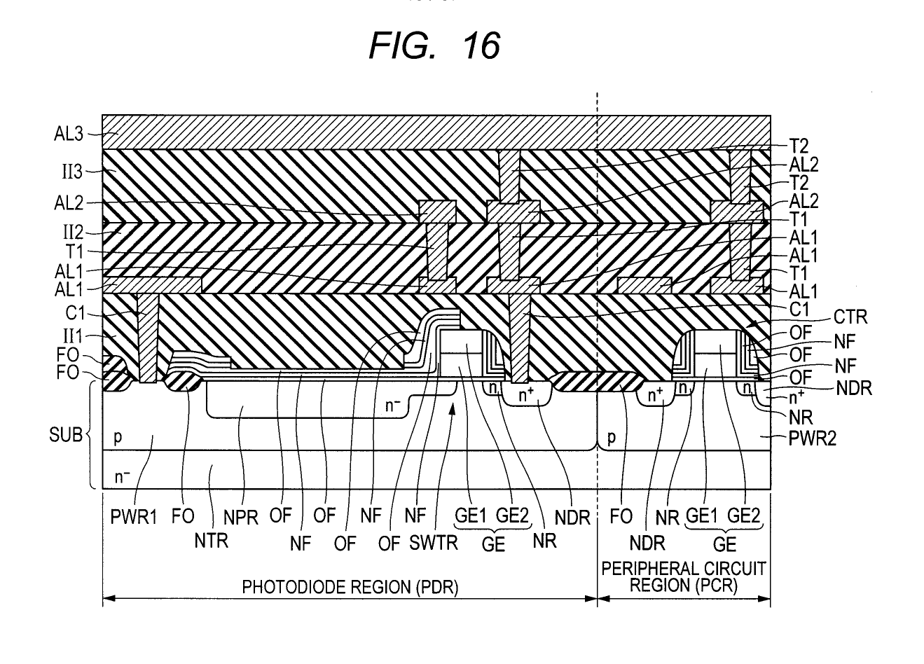

As illustrated in FIG. 16, the thin film AL3 is formed over the interlayer insulating film II3 with the conductive layer T2 formed therein by, for example, sputtering both in the photodiode region PDR and in the peripheral circuit region PCR. The thin film AL3 has the laminated structure illustrated in FIG. 5. The thin film AL3 is configured by laminating the following layers and films in the following order: the barrier layer BRL, 23 nm in thickness (in the vertical direction in FIG. 16) formed of, for example, titanium nitride; the metal layer AL3a, 600 nm in thickness, formed of aluminum; the antireflection film ARF1, 20 nm in thickness, formed of titanium nitride; and the antireflection film ARF2, 10 nm in thickness, formed of titanium. The total thickness of the thin film AL3 is 653 nm.

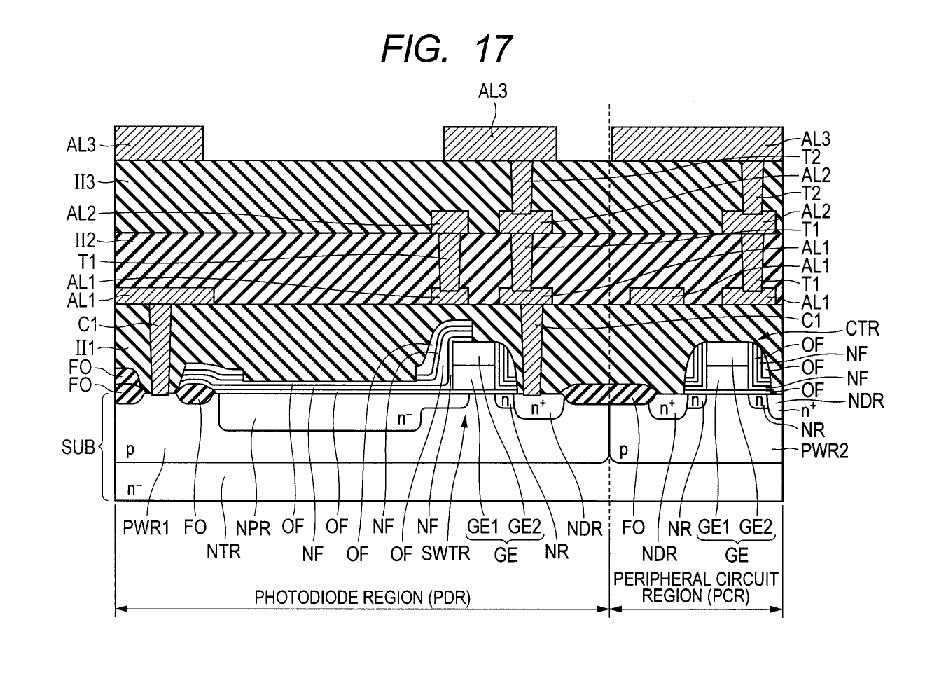

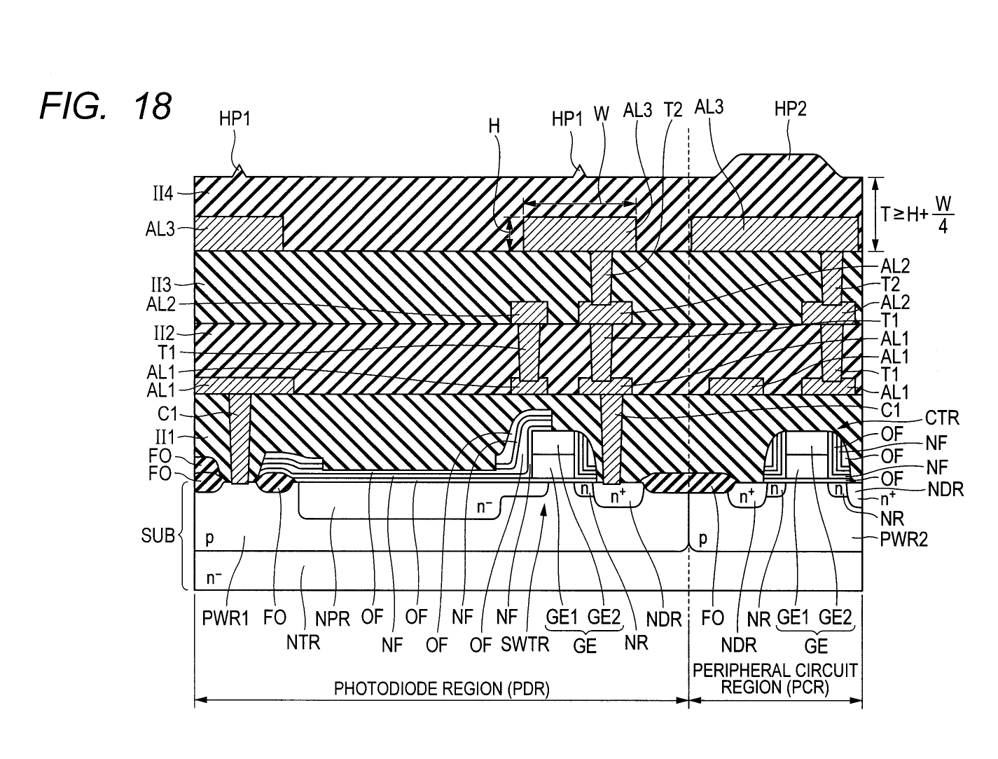

As illustrated in FIG. 17, the thin film AL3 is patterned by ordinary photoengraving process and etching process to form the metal wiring AL3 both in the photodiode region PDR and in the peripheral circuit region PCR. As an example, the maximum width of the metal wiring AL3 in the horizontal direction in the photodiode region PDR is 1669 nm.

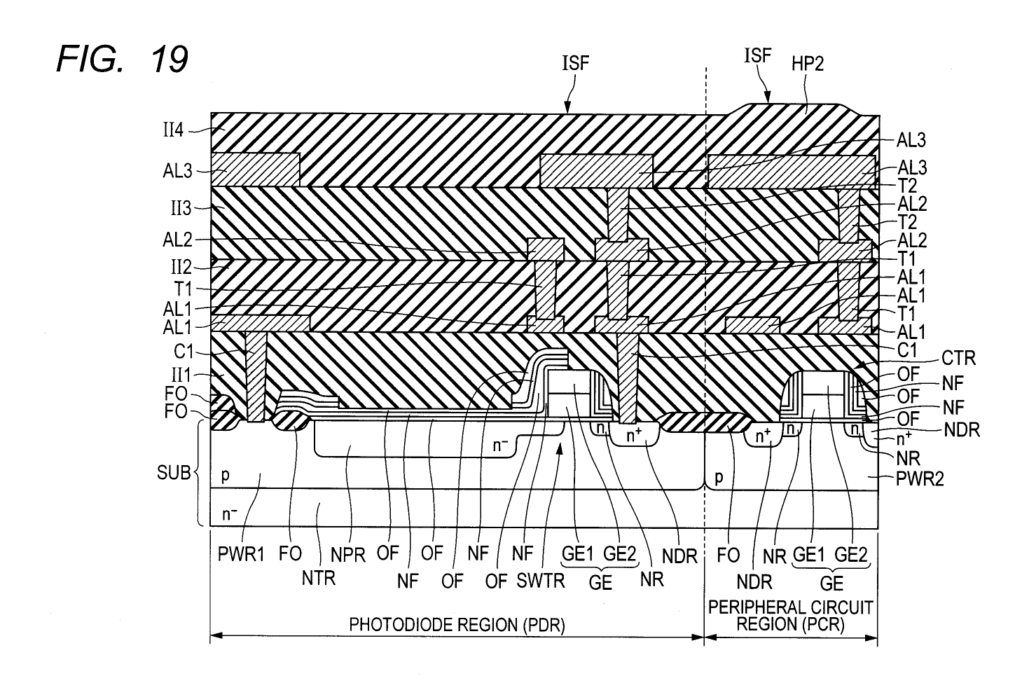

As illustrated in FIG. 18, the interlayer insulating film II4 is formed over the interlayer insulating film II3 and the metal wiring AL3 by, for example, an HDP-CVD method both in the photodiode region PDR and in the peripheral circuit region PCR. The cross-sectional shape of the interlayer insulating film II4 formed at this time is a triangular shape HP1 with the top pointed, especially, over the areas turned into a step due to the metal wiring AL3, especially, in the photodiode region PDR. The cross-sectional shape of the interlayer insulating film II4 is the following shape, especially, over the areas turned into a step due to the metal wiring AL3 in the peripheral circuit region PCR: the shape of an insulating film step HP2 higher than the insulating film step HP1 in the vertical direction and wider than the same in the horizontal direction.

It is desirable that the interlayer insulating film II4 should be formed so that the thickness T of the interlayer insulating film II4 from the uppermost surface of the interlayer insulating film II3 (in the vertical direction in the drawing) meets the following relation: the relation of T≧H+W/4, where W is the length of the diagonal lines of each intersecting portion illustrated in FIG. 6 in the pattern of the metal wiring AL3 formed in the photodiode region PDR; and H is the height of the pattern in the vertical direction in the drawing. In this example, especially, it is desirable that the interlayer insulating film II4 should be formed so that the relation of T≧H+W/4 holds, where T is the thickness of the interlayer insulating film II4 in areas where the metal wiring AL3 is not placed in the photodiode region PDR. However, also in the peripheral circuit region PCR, for example, the thickness T of the interlayer insulating film II4 may meet the relational expression of T≧H+W/4. When each intersecting portion in the pattern of the metal wiring AL3 having the above thickness is formed in a square shape, for example, it is desirable that the relation of T≧1243 nm holds. In this embodiment, the film is so formed that the relation of T=1300 nm holds. It is desirable that T should be 5 μm or below.

As illustrated in FIG. 19, an area equivalent to a certain thickness is removed (etched back) from the uppermost surface of the interlayer insulating film II4 by wet etching using, for example, hydrofluoric acid (HF). This is done both in the photodiode region PDR and in the peripheral circuit region PCR. Under the above conditions, for example, the interlayer insulating film II4 is removed by a thickness of 400 nm by wet etching.

At this time, the thinner insulating film steps HP1 are removed by this wet etching. For this reason, the uppermost surface ISF of the interlayer insulating film II4, especially, in the areas where the insulating film steps HP1 are formed in the photodiode region PDR is flattened. Meanwhile, the thicker insulating film step HP2 is reduced in profile by this wet etching; however, the insulating film step HP2 still remains even after wet etching. That is, even after the wet etching, a step is left in the insulating film surface ISF in the peripheral circuit region PCR.

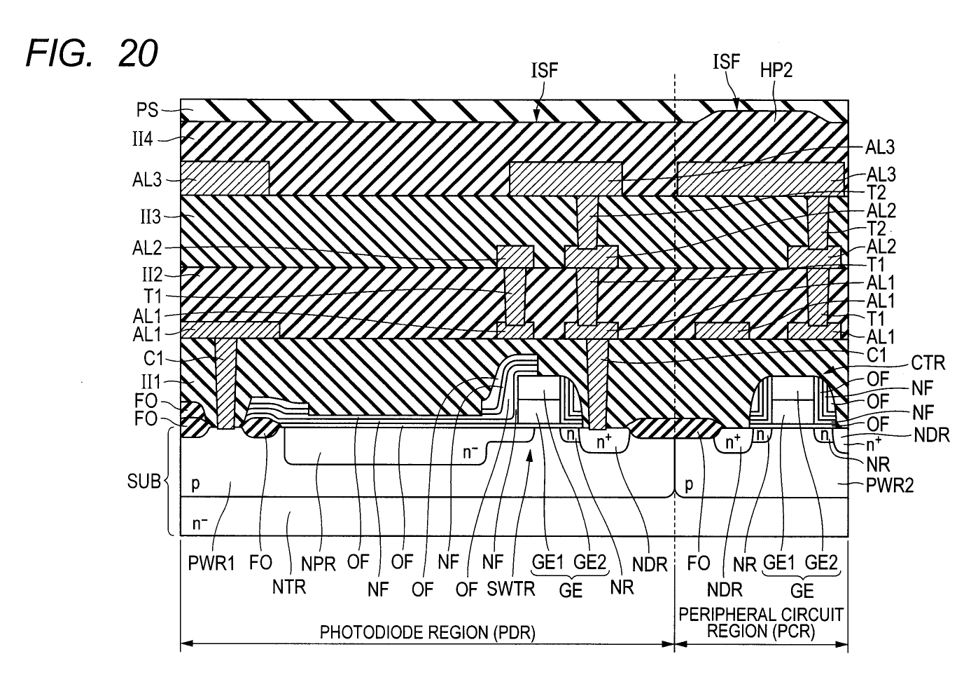

As illustrated in FIG. 20, a silicon nitride film is deposited over the interlayer insulating film II4 by, for example, a CVD method both in the photodiode region PDR and in the peripheral circuit region PCR. This silicon nitride film becomes the passivation film PS.

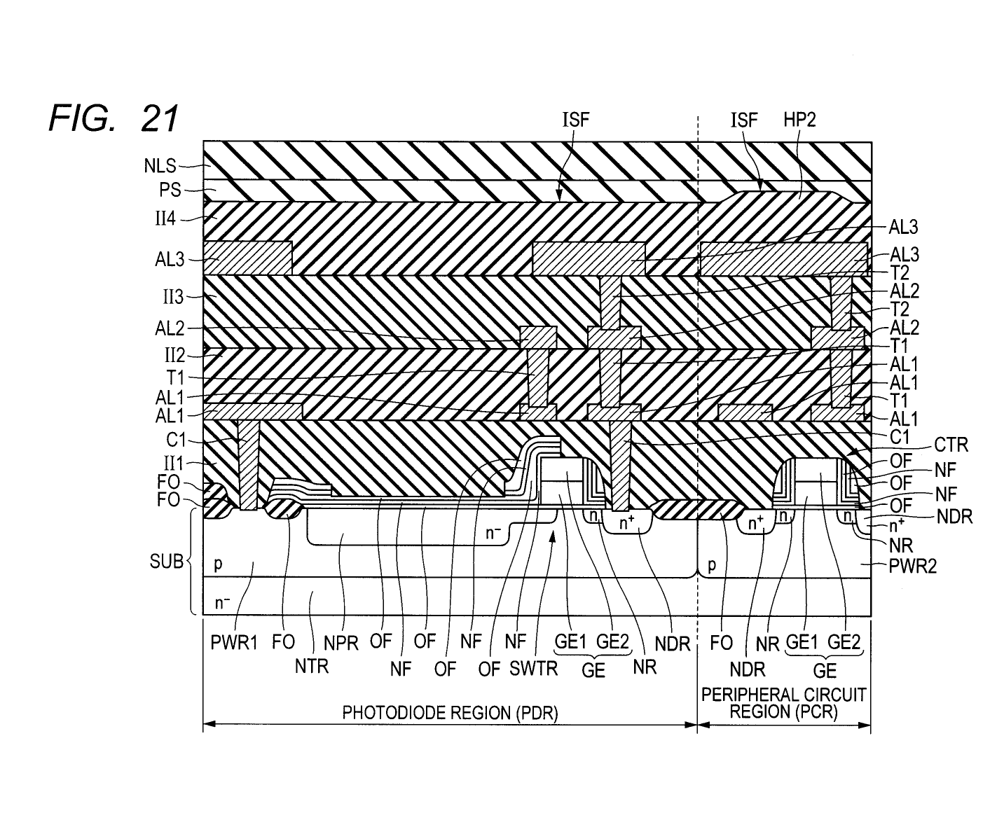

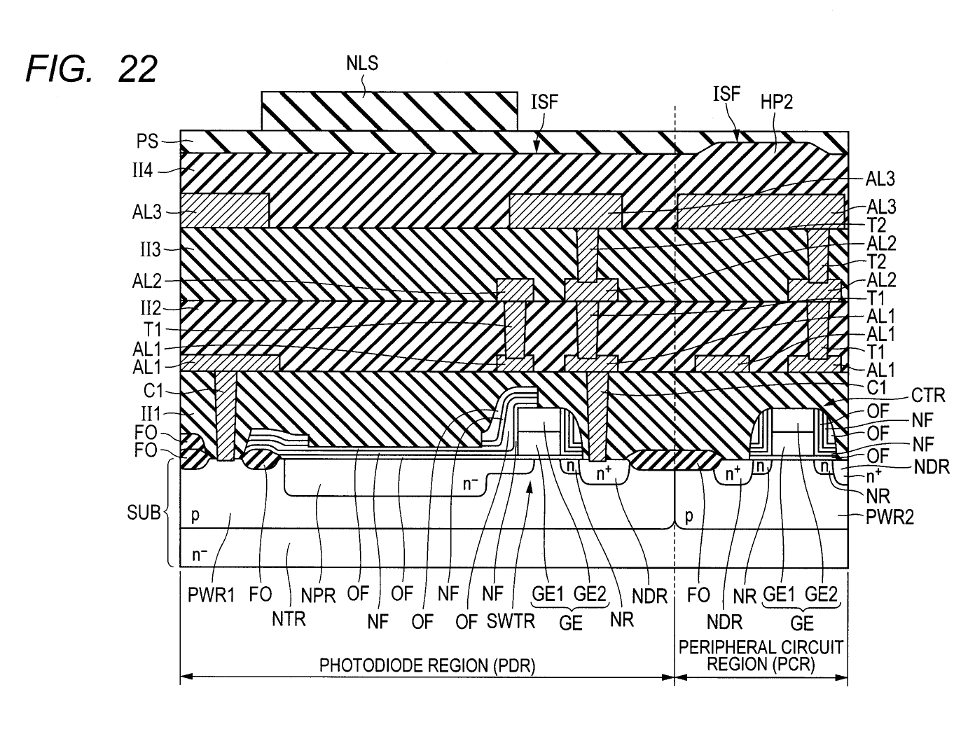

As illustrated in FIG. 21, a lens layer NLS made up of, for example, a silicon nitride film is formed both in the photodiode region PDR and in the peripheral circuit region PCR.

As illustrated in FIG. 22, the lens layer NLS is patterned by ordinary photoengraving process and etching process so that the lens layer NLS is left over the p-n junction of the photodiode PD. Thereafter, end portions of the lens layer NLS are etched back and removed and the cross-sectional shape of the condenser lens LS illustrated in FIG. 4 is obtained. The image sensor shown in FIG. 4 is formed by the above-mentioned steps.

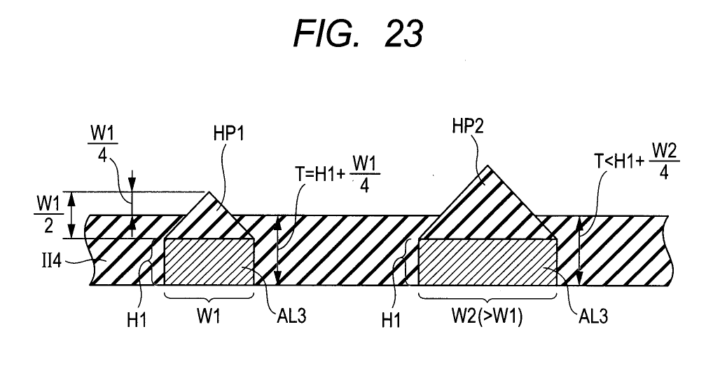

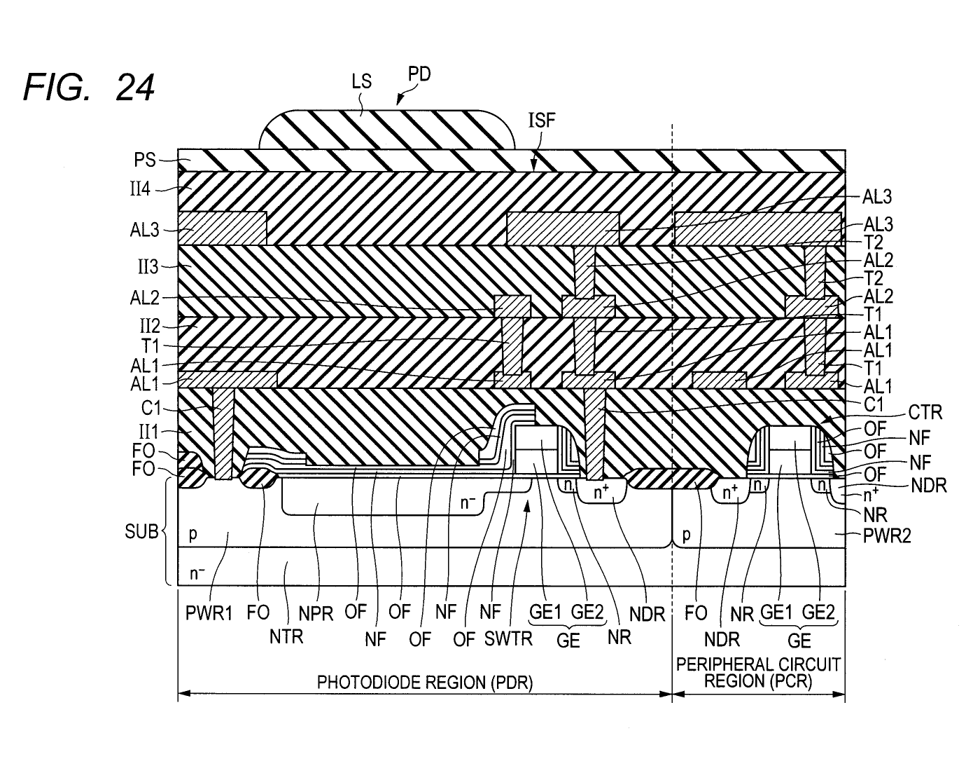

More detailed description will be given to the step of forming the interlayer insulating film II4 illustrated in FIG. 18. As illustrated in FIG. 23, it will be assumed that the left metal wiring AL3 is formed in the photodiode region PDR and is H1 in height and the length of the diagonal lines of each intersecting portion in the metal wiring AL3 illustrated in FIG. 6 is W1. In addition, it will be assumed that the right metal wiring AL3 is formed in the peripheral circuit region PCR and is H1 in height and the length of the diagonal lines of each intersecting portion in the metal wiring AL3 is W2 (>W1).

In the example in FIG. 23, the interlayer insulating film II4 whose thickness T from the lowermost part of the metal wiring AL3 is T=H1+W1/4 is formed by an HDP-CVD method. At this time, triangular steps HP1, HP2 are formed also in the uppermost surface of the interlayer insulating film II4 over the metal wiring AL3 that makes a step for the lower layer. However, since the left metal wiring AL3 in FIG. 23 is as small as W1 in the length of the diagonal lines of each intersecting portion in the metal wiring AL3, the insulating film step HP1 is also relatively small. Meanwhile, since the right metal wiring AL3 in FIG. 23 is as large as W2 in width, the insulating film step HP2 is also large. If the thickness of the interlayer insulating film II4 is H1+W2/4, the size of the insulating film step HP2 is equal to the size of the insulating film step HP1 in the following case: a case where the thickness of the interlayer insulating film II4 illustrated in FIG. 23 is H1+W1/4. However, the thickness T of the interlayer insulating film II4 in FIG. 23 is T<H1+W2/4. For this reason, the insulating film step HP2 is larger than the insulating film step HP1. At the subsequent step of wet etching (Refer to FIG. 19), therefore, the step HP1, which is small in the amount to be removed to flatten the uppermost surface, is removed and the step HP2 is partly left.

When the interlayer insulating film having a thickness of T=H1+W1/4 is formed over the metal wiring AL3 H1 in height and W1 in the length of the diagonal lines of each intersecting portion therein, the following can be implemented: so small a step that it is flattened by slight etching can be formed in the interlayer insulating film. It can be seen from the above numerical formula that as the width of a metal wiring is increased, the film thickness of an interlayer insulating film required to minimize a step in the interlayer insulating film thereover is increased.

Description will be given to the action and effect of this embodiment with reference to a comparative example to this embodiment. First, description will be given to FIG. 24 to FIG. 27 illustrating the comparative example.

In a publicly known image sensor, as illustrated in FIG. 24, the flatness of the uppermost surface ISF of the interlayer insulating film II4 is substantially equal both in the photodiode region PDR and in the peripheral circuit region PCR. That is, the uppermost surface ISF of the interlayer insulating film II4 in the peripheral circuit region PCR is also flat similarly to the uppermost surface ISF of the interlayer insulating film II4 in the photodiode region PDR.

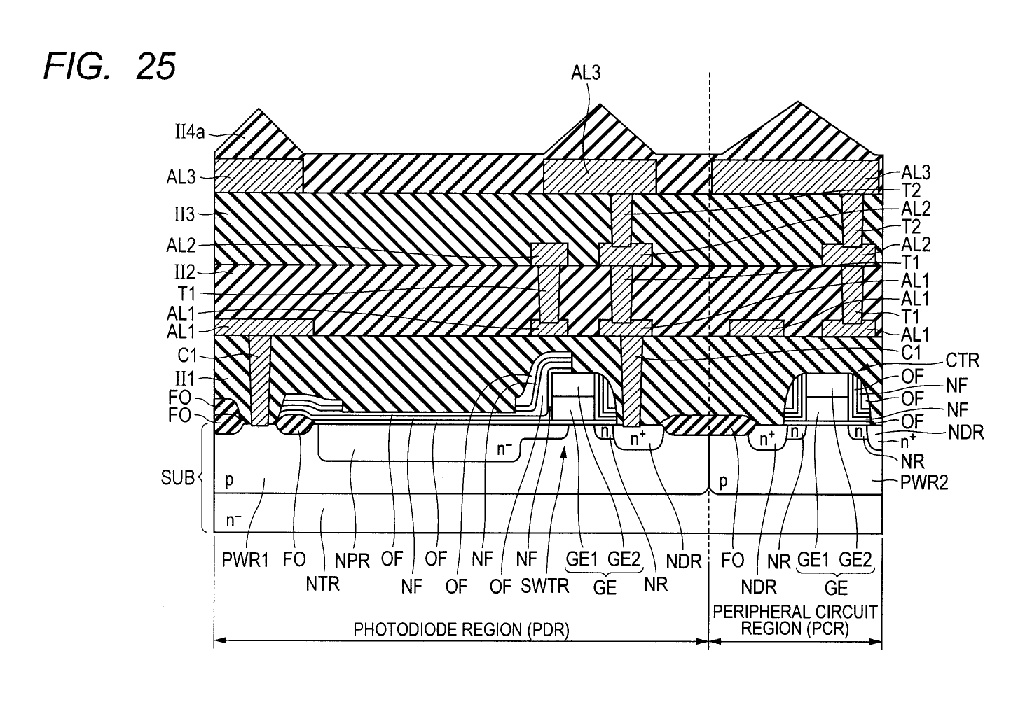

In FIG. 25 to FIG. 27, the configuration of the interlayer insulating film II2 and the lower layers is the same as in the first embodiment. As illustrated in FIG. 25, the following processing is carried out after the step illustrated in FIG. 17 in the first embodiment: the same interlayer insulating film II4a as the interlayer insulating film II4 in FIG. 18 is formed by, for example, an HDP-CVD method both in the photodiode region PDR and in the peripheral circuit region PCR.

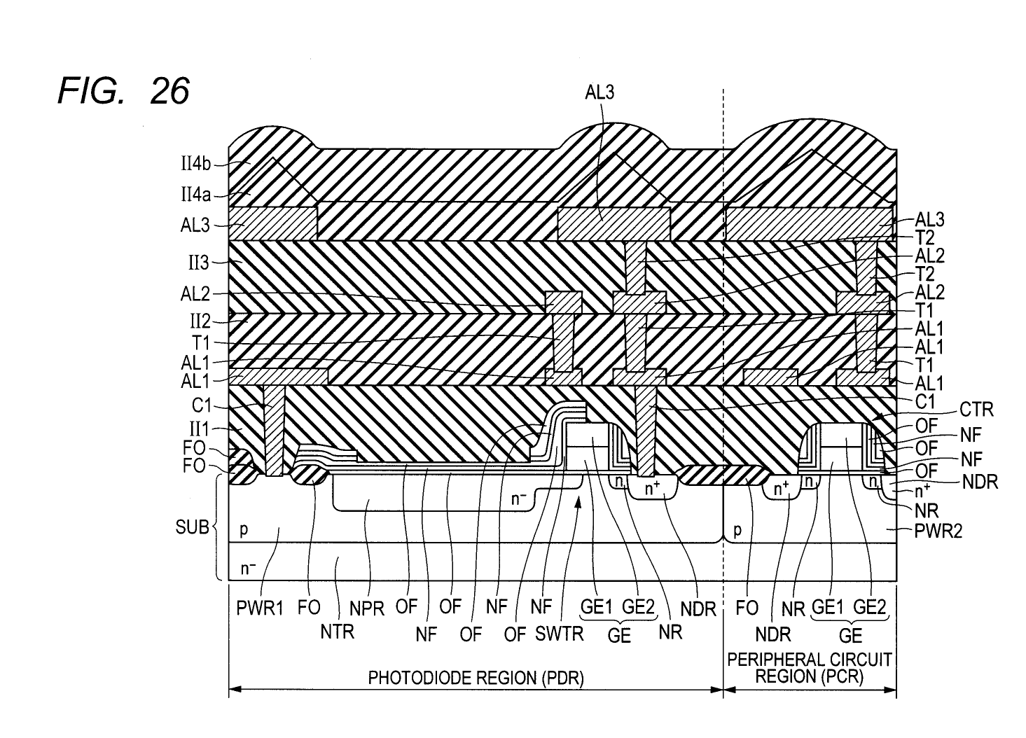

As illustrated in FIG. 26, an interlayer insulating film II4b made up of a silicon oxide film (especially, TEOS) is formed over the interlayer insulating film II4a by, for example, a plasma CVD method. It is formed both in the photodiode region PDR and in the peripheral circuit region PCR.

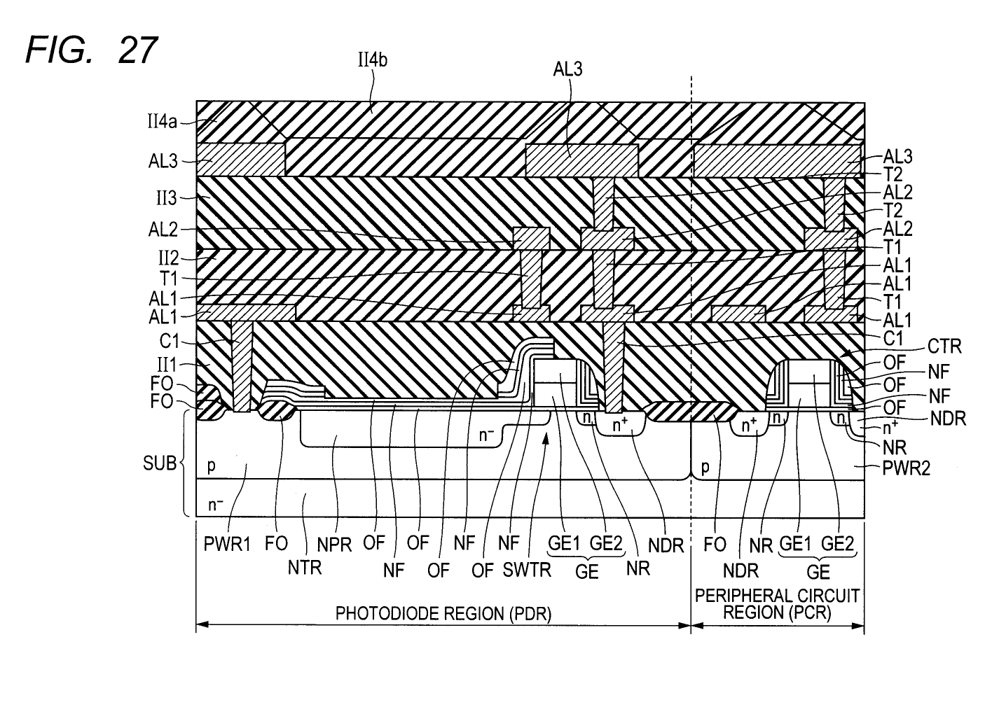

As illustrated in FIG. 27, an area equivalent to a certain thickness is removed from the uppermost surfaces of the interlayer insulating films II4a, II4b by, for example, CMP both in the photodiode region PDR and in the peripheral circuit region PCR. In this example, the processing is carried out until the uppermost surfaces of the interlayer insulating films are flattened both in the photodiode region PDR and in the peripheral circuit region PCR.

In the above comparative example, it is desirable to carry out processing so that the uppermost surface of the interlayer insulating film is flattened to some extent when it is formed at the step in FIG. 26. If CMP is carried out on a plane inferior in flatness, there is a possibility that the surface has a concavo-convex shape like a mortar and is inferior in uniformity after the CMP. When the interlayer insulating film formed by an HDP-CVD method is formed over a wide step in the peripheral circuit region PCR, a large step is formed. When a plasma CVD method is used, it is difficult to form the interlayer insulating film so that the areas sandwiched between adjoining parts of metal wiring are filled.

According to the above theory, some sort of problem arises in an interlayer insulating film when it is formed using only either an HDP-CVD method or a plasma CVD method. In the comparative example, to cope with this, both an HDP-CVD method and a plasma CVD method are used to form the interlayer insulating film II4a and the interlayer insulating film II4b.

To make the interlayer insulating films flatter, it is desirable to form them thicker. In this case, however, the formed image sensor is degraded in light receiving characteristic. For this reason, the interlayer insulating film II4b formed thick is polished and removed by a considerable thickness at a subsequent step.

In the method in the comparative example, as mentioned above, the following processing is carried out to flatten the uppermost surface of the interlayer insulating film II4 in the photodiode region PDR and the peripheral circuit region PCR: it is formed to a considerable thickness and then most thereof is polished and removed. This increases a production cost and degrades productivity.

In this embodiment, meanwhile, only the interlayer insulating film II4 in the photodiode region PDR at minimum is processed so that the uppermost surface ISF thereof is flattened. For this reason, the following can be implemented: the thickness T of the interlayer insulating film II4 to be formed at minimum can be made equal to H+W/4, which is smaller than in the comparative example; and the thickness from the uppermost surface ISF of the interlayer insulating film II4 to be removed by wet etching at a subsequent step can be reduced.

When the insulating film step HP1 is etched back by wet etching, the interlayer insulating film II4 after this processing can be made thinner. In the example in which the above dimensions are adopted, the thickness of the interlayer insulating film II4 over the metal wiring AL3 in the photodiode region PDR is 247 nm. When the interlayer insulating film II4 is thinned as mentioned above, especially, the light receiving sensitivity of the photodiode PD is enhanced and light diffusion is suppressed. As a result, the performance of the image sensor is further enhanced.

In this embodiment, CMP is omitted. Therefore, the occurrence of problems, such as dishing, in the uppermost surface ISF due to CMP on the interlayer insulating film II4 can be suppressed.

If such flattening processing as illustrated in FIG. 19 is not carried out after the interlayer insulating film II4 is formed as illustrated in FIG. 18, the following takes place: though the uppermost surface ISF of the interlayer insulating film II4 is not completely flat, any functional problem does not arise at least in the photodiode PD. FIG. 23 illustrating the mode and dimension of the interlayer insulating film II4 in FIG. 18 will be referred to again. After the step in FIG. 18, the interlayer insulating film 114 approximately W1/2 in thickness is formed over the left metal wiring AL3. This can be approximately obtained on the assumption that the interlayer insulating film II4 over the metal wiring AL3 is in the shape of an isosceles triangle with the apical angle substantially orthogonal. In addition, the thickness T of the interlayer insulating film II4 in areas where the metal wiring AL3 is not placed in the photodiode region PDR is H1+W1/4. Therefore, the height of the step HP1 in areas other than the metal wiring AL3 as viewed from the uppermost surface of the interlayer insulating film II4 is W1/4. As mentioned above, when the height of the step HP1 is 25% or below of the width of the metal wiring AL3 (length of the diagonal lines of each intersecting portion), the surface containing the step HP1 is defined as flat. For this reason, even though the manufacturing flow proceeds to the step in FIG. 20 with the work piece in the state in FIG. 18 (FIG. 23), no practical problem arises in the image sensor, especially, in the following cases: cases where it is unnecessary to form the lens layer NLS or condenser lens LS illustrated in FIG. 21 and FIG. 22.

### Second Embodiment

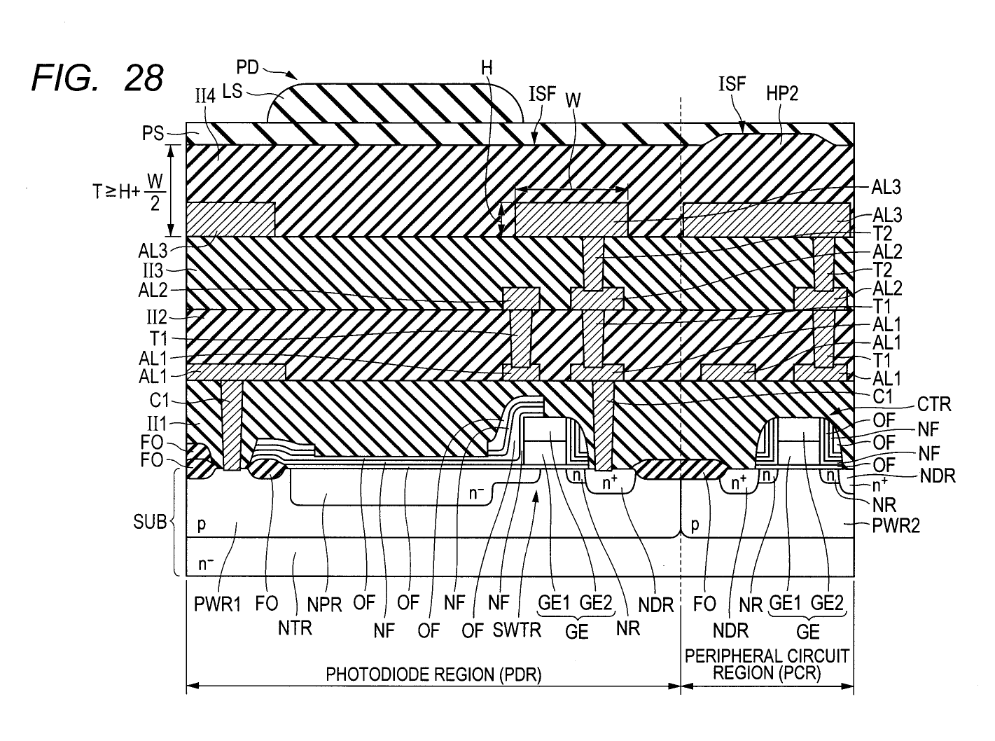

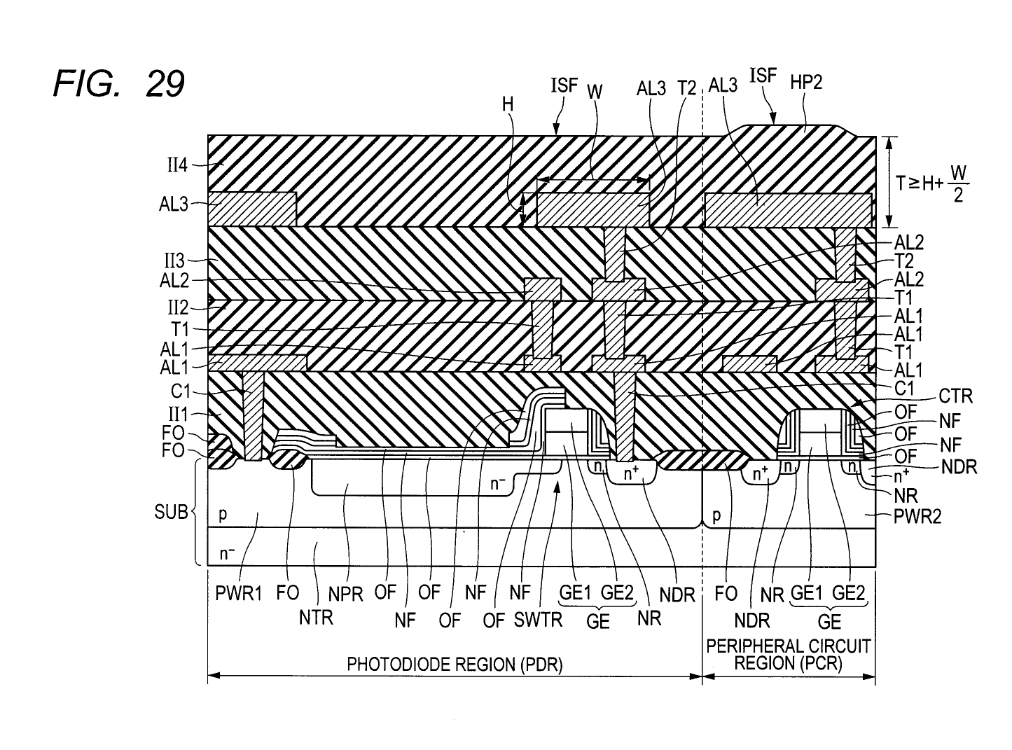

This embodiment is different from the first embodiment in the method of forming the interlayer insulating film II4. Hereafter, description will be given to the manufacturing method of the semiconductor device (image sensor) in this embodiment with reference to FIG. 28 to FIG. 30.

As illustrated in FIG. 28, the image sensor in this embodiment has substantially the same configuration as the image sensor in the first embodiment illustrated in FIG. 4. However, this embodiment is different from the first embodiment in that the thickness T of the interlayer insulating film II4 is larger than in the first embodiment.

Specific description will be given. The thickness T of the interlayer insulating film II4 from the uppermost surface of the interlayer insulating film II3 (in the vertical direction in the drawing) meets the relation of T≧H+W/2, where W is the length of the diagonal lines of each intersecting portion in the pattern of the metal wiring AL3 formed in the photodiode region PDR; and H is the height of the pattern in the vertical direction.

The semiconductor device in the second embodiment is different from the semiconductor device in the first embodiment only in this respect. It is the same as the semiconductor device in the first embodiment in the other respects.

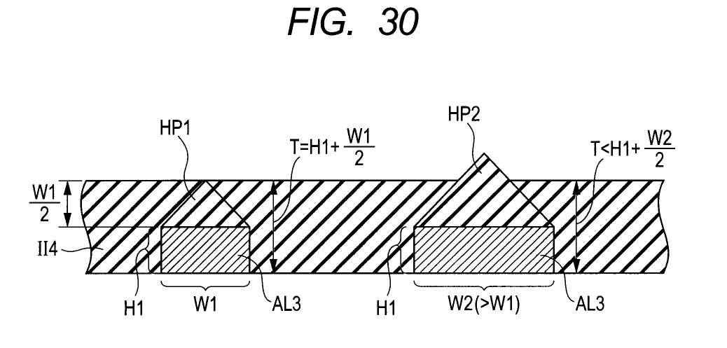

Description will be given to a manufacturing method of the semiconductor device in this embodiment with reference to FIG. 29 and FIG. 30.

Also in this embodiment, the steps illustrated in FIG. 8 to FIG. 17 are the same as those in the first embodiment. After the step illustrated in FIG. 17, the same interlayer insulating film II4 as in FIG. 18 is formed by an HDP-CVD method both in the photodiode region PDR and in the peripheral circuit region PCR as illustrated in FIG. 29. In this embodiment, however, the film thickness of the interlayer insulating film II4 is controlled so that T≧H+W/2 as mentioned above. When each intersecting portion in the pattern of the metal wiring AL3 having the same width and thickness as in the first embodiment is formed in a square shape, for example, it is desirable that the relation of T≧1833 nm should hold. Also in this embodiment, it is desirable that T should be 5 μm or below.

As illustrated in FIG. 30, the interlayer insulating film II4 is so formed that T≧H1+W1/2 when the metal wiring AL3 in the photodiode region PDR is W1 in the length of the diagonal lines of each intersecting portion. In this case, the step HP1 that would be otherwise formed in the uppermost surface of the interlayer insulating film II4 is hardly identified. This is because the height of the interlayer insulating film II4 substantially in the shape of rectangular equilateral triangle formed over the metal wiring AL3 from the metal wiring AL3 is substantially W1/2. That is, in this case, the interlayer insulating film II4 is flat over the metal wiring AL3 in the photodiode region PDR. In the peripheral circuit region PCR, meanwhile, the metal wiring AL3, W2 in the length of the diagonal lines of each intersecting portion, larger than W1 of the length of the diagonal lines of each intersecting portion, is formed. For this reason, to form a flat interlayer insulating film II4 over the metal wiring AL3, a thickness of H1+W2/2 or above is required. When the interlayer insulating film II4 having a thickness T of H1+W1/2 is formed, T<H1+W2/2. For this reason, a step HP2 is formed in the uppermost surface of the interlayer insulating film II4 over the metal wiring AL3 in the peripheral circuit region PCR.

After the step illustrated in FIG. 29, the same steps as those in FIG. 20 to FIG. 22 are carried out and the image sensor illustrated in FIG. 28 is formed.

Description will be given to the action and effect of this embodiment. When the uppermost surface of the interlayer insulating film II4 in the photodiode region PDR is flat, as mentioned above, no special problem arises in ensuring the functionality of the photodiode PD. In the invention, the interlayer insulating film II4 having a thickness of T≧H+W/2 is formed using an HDP-CVD method; and in this embodiment, further, the uppermost surface of the interlayer insulating film II4 in the photodiode region PDR is flattened more than in the first embodiment. In this case, for the above-mentioned reason, the necessity for processing of flattening a step at a subsequent step is obviated even though the step is formed in the peripheral circuit region PCR. In this embodiment, that is, the following can be implemented without flattening a step at a subsequent step in various cases, including cases where the condenser lens LS is formed: so high flatness that the performance of the photodiode PD can be ensured can be obtained. For this reason, steps related to the interlayer insulating film II4 can be reduced more than in the first embodiment. That is, the production cost of the semiconductor device can be further reduced.

In this embodiment, the thickness to which the interlayer insulating film II4 is formed is increased as compared with the first embodiment. However, when this thickness (H+W/2 or above) is slightly larger than the thickness (H+W/4 or above) in the first embodiment, the occurrence of problems, such as degradation in the performance of the image sensor, can be suppressed.

In this embodiment, CMP is omitted. Therefore, the occurrence of problems, such as dishing, in the uppermost surface ISF due to CMP on the interlayer insulating film II4 can be suppressed. In addition, the production cost can be reduced.

The second embodiment of the invention is different from the first embodiment of the invention only in the above-mentioned respects. That is, with respect to the second embodiment of the invention, the configurations, conditions, procedures, effects, and the like that are not described above are all in accordance with those in the first embodiment of the invention.

### Third Embodiment

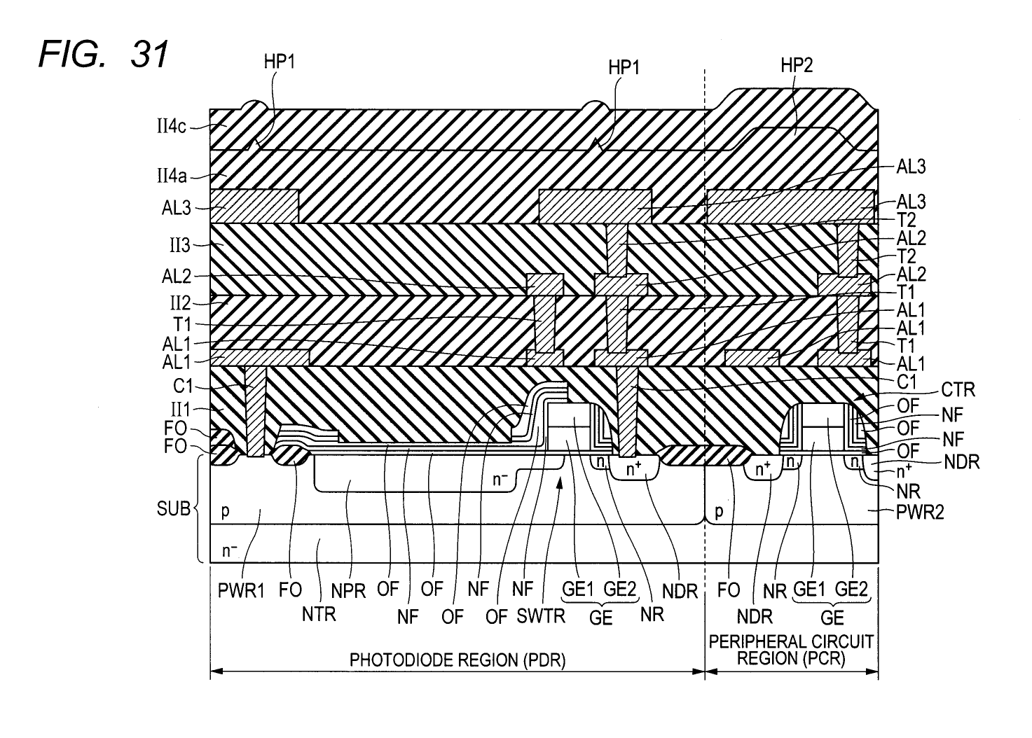

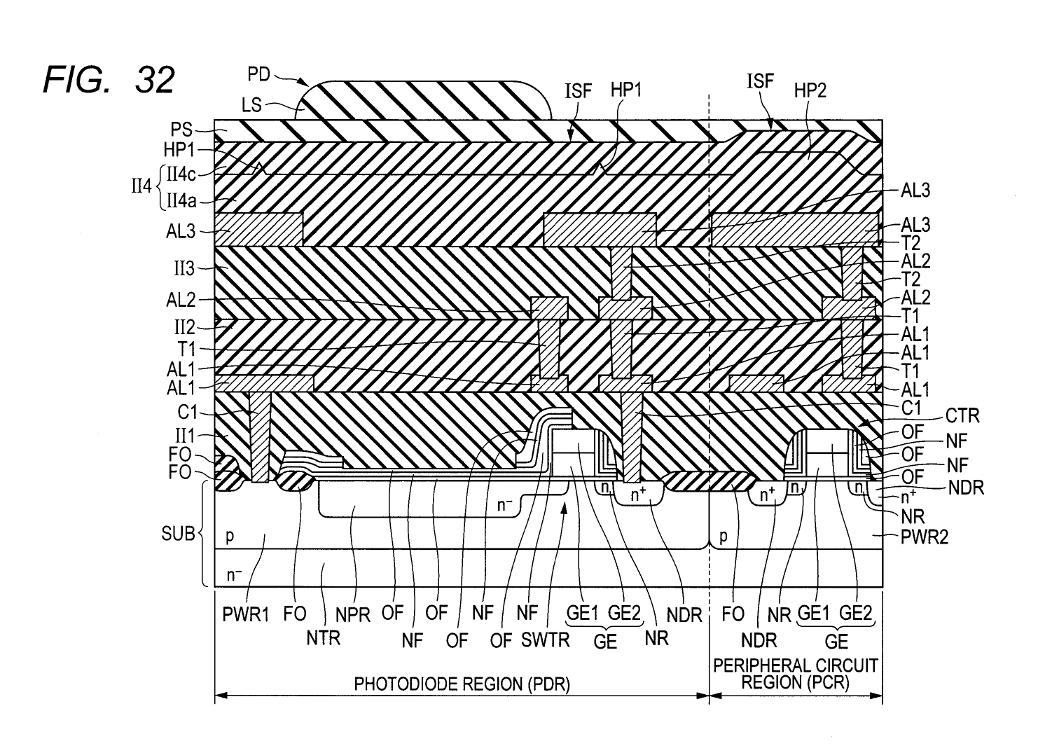

This embodiment is different from the first embodiment in the method of forming the interlayer insulating film II4. Hereafter, description will be given to the manufacturing method of the semiconductor device (image sensor) in this embodiment with reference to FIG. 31 and FIG. 32.

Also in this embodiment, the steps illustrated in FIG. 8 to FIG. 18 are the same as those in the first embodiment. That is, also in this embodiment, the following interlayer insulating film 114 is formed by, for example, an HDP-CVD method as in the first embodiment: the interlayer insulating film II4 having a thickness T that meets the relation of T≧H+W/4 (for example, the thickness from the uppermost surface of the interlayer insulating film II3 is 1300 nm). Thus the steps HP1, HP2 are formed.

As illustrated in FIG. 31, an interlayer insulating film II4c (second interlayer insulating film) made up of a silicon oxide film (especially, BPTEOS) is formed by a plasma CVD method after the step illustrated in FIG. 18. It is formed both in the photodiode region PDR and in the peripheral circuit region PCR. In this example, it is desirable to form the interlayer insulating film II4c so that the following is implemented: the thickness obtained by adding those of the interlayer insulating film II4a and the interlayer insulating film II4c is such a thickness that the light receiving sensitivity of the image sensor is not degraded. The interlayer insulating film 114a in FIG. 31 is equivalent to the interlayer insulating film 114 in FIG. 18 formed by an HDP-CVD method.

Thereafter, the interlayer insulating film II4c is heat treated. Thus the interlayer insulating film II4c flows and is partway flattened because it comprised of BPTEOS is low in softening point. At this time, the following takes place as in each of the above embodiments: the uppermost surface of the interlayer insulating film II4c in the photodiode region PDR is flattened but a step is left in the uppermost surface of the interlayer insulating film II4c in the peripheral circuit region PCR.

After the heat treatment, the same steps as those in FIG. 20 to FIG. 22 are carried out and the image sensor illustrated in FIG. 32 is formed. In FIG. 32, what is obtained by combining the interlayer insulating film II4a and the interlayer insulating film 114c is defined as the interlayer insulating film II4 over the uppermost-layer wiring.

Description will be given to the action and effect of this embodiment. In this embodiment, as mentioned above, the uppermost surface of the interlayer insulating film II4c is flattened utilizing the properties of BPTEOS that it is caused to flow by heat treatment and is easy to flatten. Since the step HP1 arising from a step of the metal wiring AL3 is minute, the interlayer insulating film II4c in the photodiode region PDR is flattened by the above-mentioned flattening processing. Since the step HP2 is large, meanwhile, a step is left in the interlayer insulating film 114c in the peripheral circuit region PCR even after the flattening processing. The action and effect obtained by this are the same as those in each of the above embodiments.

In this embodiment, degradation in the functionality of the image sensor due to the excessive thickness of the entire image sensor is suppressed by controlling the film formation thickness of the interlayer insulating film II4c.

Also in this embodiment, CMP is omitted. Therefore, the occurrence of problems, such as dishing, in the uppermost surface ISF due to CMP on the interlayer insulating film II4 can be suppressed. In addition, the production cost can be reduced.

The third embodiment of the invention is different from the first embodiment of the invention only in the above-mentioned respects. That is, with respect to the third embodiment of the invention, the configurations, conditions, procedures, effects, and the like that are not described above are all in accordance with those in the first embodiment of the invention.

### Fourth Embodiment

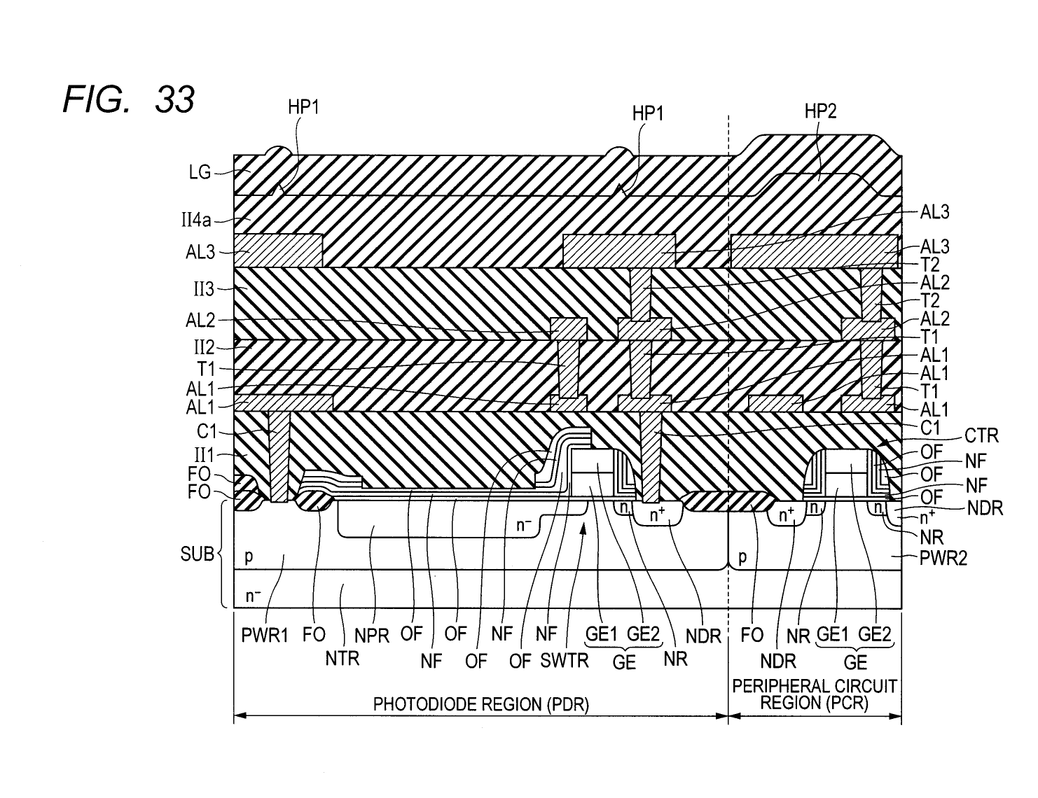

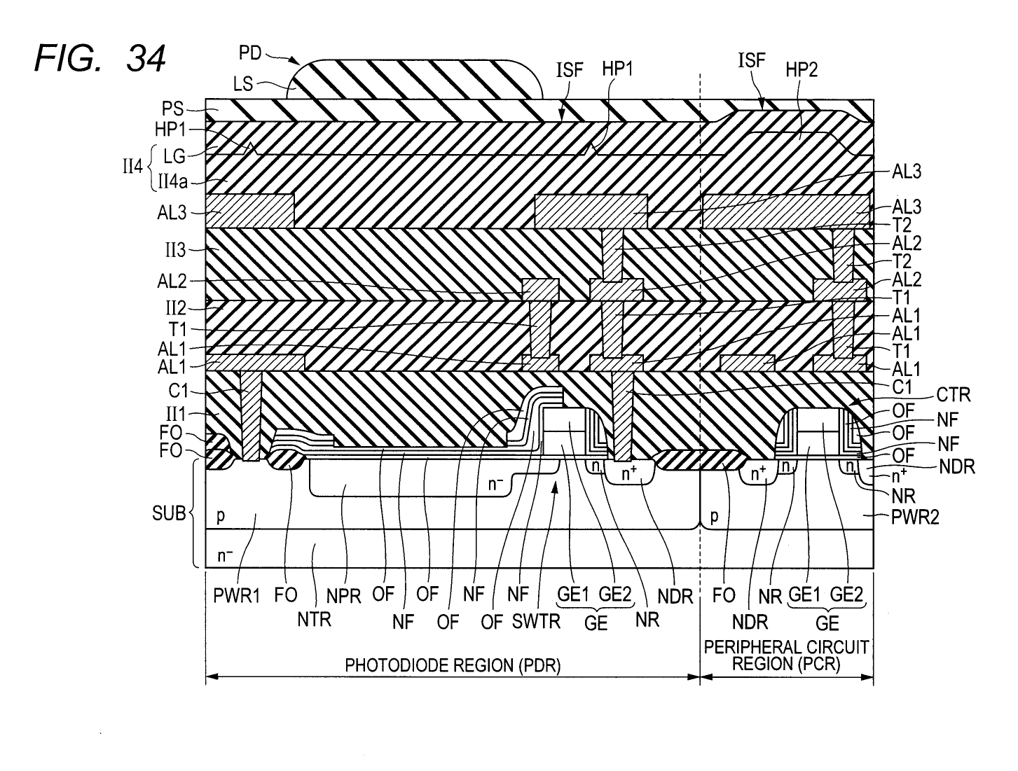

This embodiment is different from the first embodiment in the method of forming the interlayer insulating film II4. Hereafter, description will be given to the manufacturing method of the semiconductor device (image sensor) in this embodiment with reference to FIG. 33 and FIG. 34.

Also in this embodiment, the steps illustrated in FIG. 8 to FIG. 18 are the same as those in the first embodiment. That is, also in this embodiment, the following interlayer insulating film 114 is formed by, for example, an HDP-CVD method as in the first embodiment: the interlayer insulating film II4 having a thickness T that meets the relation of T≧H+W/4 (for example, the thickness from the uppermost surface of the interlayer insulating film II3 is 1300 nm). Thus the steps HP1, HP2 are formed.

As illustrated in FIG. 33, liquid glass LG, such as SOG (Spin On Glass), is applied to the interlayer insulating film II4a from above both in the photodiode region PDR and in the peripheral circuit region PCR after the step illustrated in FIG. 18. SOG is a liquid obtained by dissolving silica (SiO₂) whose composition is the same as that of the silicon oxide film in solvent. For example, liquid glass LG is dripped onto the interlayer insulating film II4a and then the entire semiconductor substrate SUB is rotated in the direction along the main surface thereof. At this time, the dripped liquid glass LG is evenly spread throughout the wafer including over the interlayer insulating film II4a. The uppermost surface of this liquid glass LG is flattened. In this example, it is desirable to apply the liquid glass LG so that the following is implemented: the thickness obtained by adding those of the interlayer insulating film II4a and the flattened liquid glass LG is such a thickness that the light receiving sensitivity of the image sensor is not degraded. The interlayer insulating film II4a in FIG. 33 is equivalent to the interlayer insulating film II4 in FIG. 18 formed by an HDP-CVD method.

At this time, the uppermost surface of the liquid glass LG in the photodiode region PDR is flattened but a step is left in the uppermost surface of the liquid glass LG in the peripheral circuit region PCR as in each of the above embodiments.

After the liquid glass LG is applied, the same steps as those in FIG. 20 to FIG. 22 are carried out and the image sensor illustrated in FIG. 34 is formed. In FIG. 34, what is obtained by combining the interlayer insulating film II4a and the liquid glass LG is defined as the interlayer insulating film II4 over the uppermost-layer wiring.

Description will be given to the action and effect of this embodiment. In this embodiment, as mentioned above, the uppermost surface of the liquid glass LG is flattened utilizing the properties that the uppermost surface of a laminated structure is flattened by SOG. Since the step HP1 in the interlayer insulating film II4a arising form a step of the metal wiring AL3 is minute, the liquid glass LG in the photodiode region PDR is flattened by the above-mentioned flattening processing. Since the step HP2 in the interlayer insulating film II4a is large, meanwhile, a step is left in the liquid glass LG in the peripheral circuit region PCR even after the flattening processing. The action and effect obtained by this are the same as those in each of the above embodiments.

In this embodiment, degradation in the functionality of the image sensor due to the excessive thickness of the entire image sensor is suppressed by controlling the thickness to which the liquid glass LG is applied.

Also in this embodiment, CMP is omitted. Therefore, the occurrence of problems, such as dishing, in the uppermost surface ISF due to CMP on the interlayer insulating film II4 can be suppressed. In addition, the production cost can be reduced.

The fourth embodiment of the invention is different from the first embodiment of the invention only in the above-mentioned respects. That is, with respect to the fourth embodiment of the invention, the configurations, conditions, procedures, effects, and the like that are not described above are all in accordance with those in the first embodiment of the invention.

### Fifth Embodiment

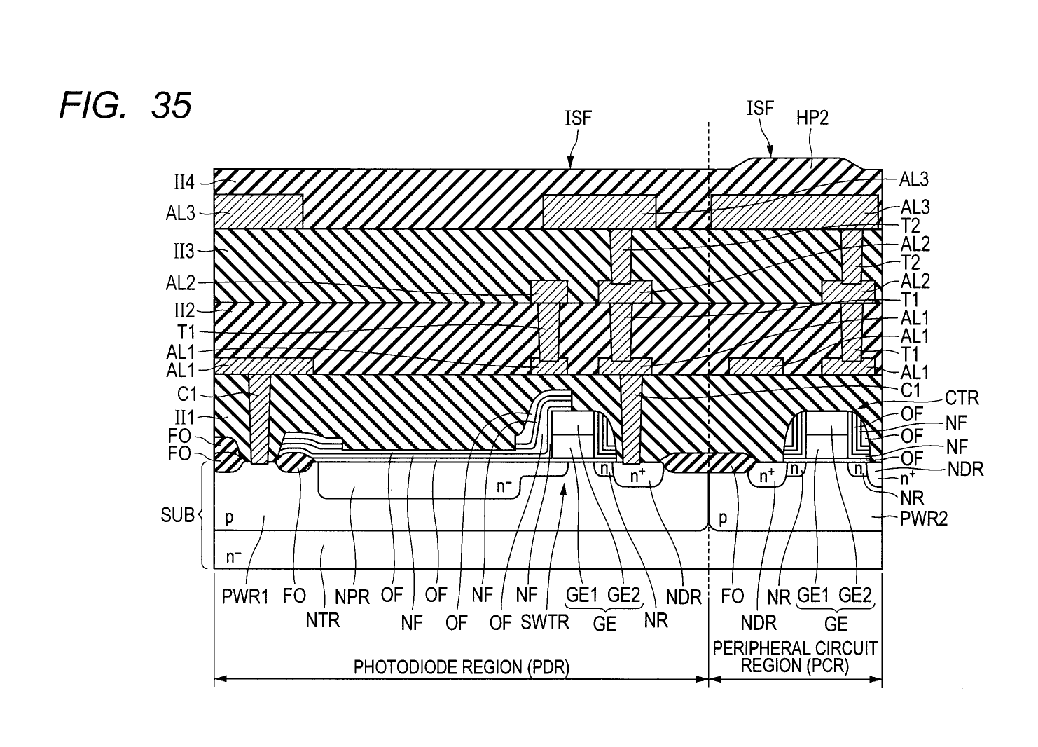

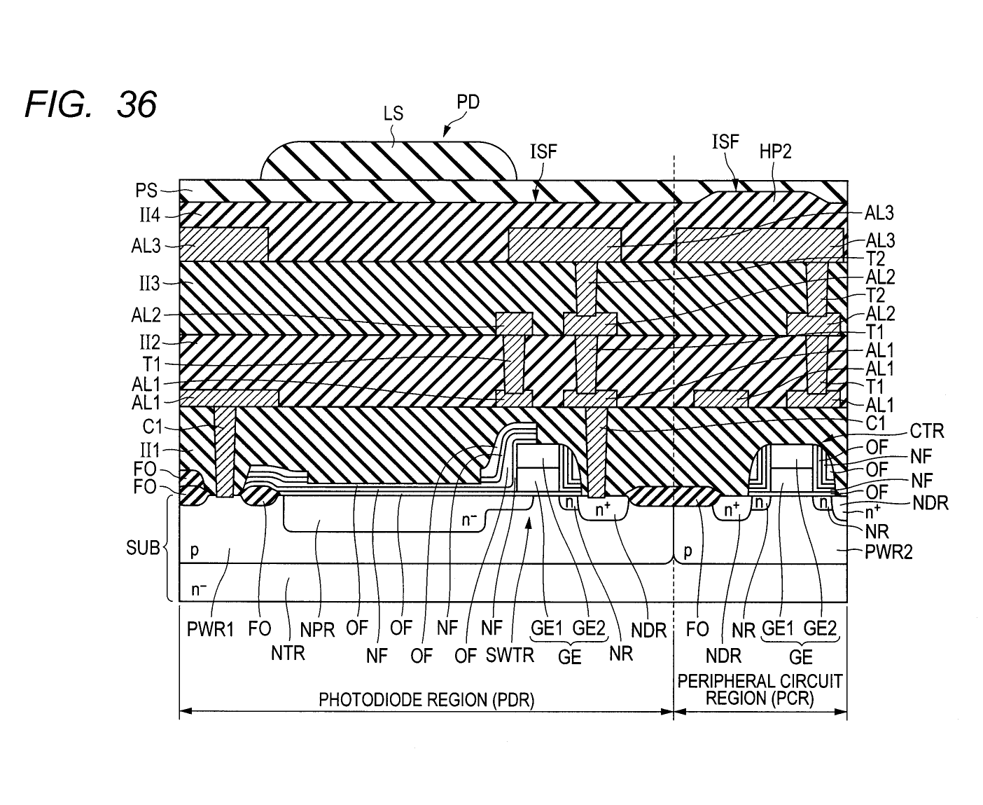

This embodiment is different from the first embodiment in the method of forming the interlayer insulating film II4. Hereafter, description will be given to the manufacturing method of the semiconductor device (image sensor) in this embodiment with reference to FIG. 35 and FIG. 36.

Also in this embodiment, the steps illustrated in FIG. 8 to FIG. 18 are the same as those in the first embodiment. That is, also in this embodiment, the following interlayer insulating film 114 is formed by, for example, an HDP-CVD method as in the first embodiment: the interlayer insulating film II4 having a thickness T that meets the relation of T≧H+W/4 (for example, the thickness from the uppermost surface of the interlayer insulating film II3 is 1300 nm). Thus the steps HP1, HP2 are formed.

As illustrated in FIG. 35, the uppermost surface ISF of the interlayer insulating film II4 is flattened by CMP after the step illustrated in FIG. 18. That is, an area equivalent to a certain thickness is polished and removed from the uppermost surface of the interlayer insulating film II4 by CMP, not by the wet etching in the first embodiment illustrated in FIG. 19 and the uppermost surface ISF is thereby flattened.

The step HP1 in the interlayer insulating film II4 in the photodiode region PDR is removed by this processing as in the first embodiment and the uppermost surface ISF in the photodiode region PDR is flattened. Meanwhile, the step HP2 in the interlayer insulating film II4 in the peripheral circuit region PCR is left. The action and effect obtained by this are the same as those in each of the above embodiments.

After the CMP is carried out, the same steps as in FIG. 20 to FIG. 22 are carried out and the image sensor illustrated in FIG. 36 is formed.

Description will be given to the action and effect of this embodiment. When the insulating film step HP1 is polished and removed by CMP in this embodiment, it is possible to make the processed interlayer insulating film II4 thinner. For example, the following takes place when the uppermost surface ISF is removed by a thickness of 400 nm by CMP in an example of the metal wiring AL3 having the dimensions in the first embodiment: the thickness of the interlayer insulating film II4 over the metal wiring AL3 in the photodiode region PDR becomes 247 nm. When the interlayer insulating film II4 is thinned, as mentioned above, especially, the light receiving sensitivity of the photodiode PD is enhanced and the performance of the image sensor is further enhanced.

The interlayer insulating film II4 formed in this embodiment is thinner than, for example, that from the manufacturing process in the comparative example in FIG. 24 to FIG. 27. In this embodiment, for this reason, both the film formation thickness and the polishing removal thickness can be reduced as in the first embodiment as compared with the comparative example. As a result, the production cost can be reduced.

The fifth embodiment of the invention is different from the first embodiment of the invention only in the above-mentioned respects. That is, with respect to the fourth embodiment of the invention, the configurations, conditions, procedures, effects, and the like that are not described above are all in accordance with those in the first embodiment of the invention.

### Sixth Embodiment

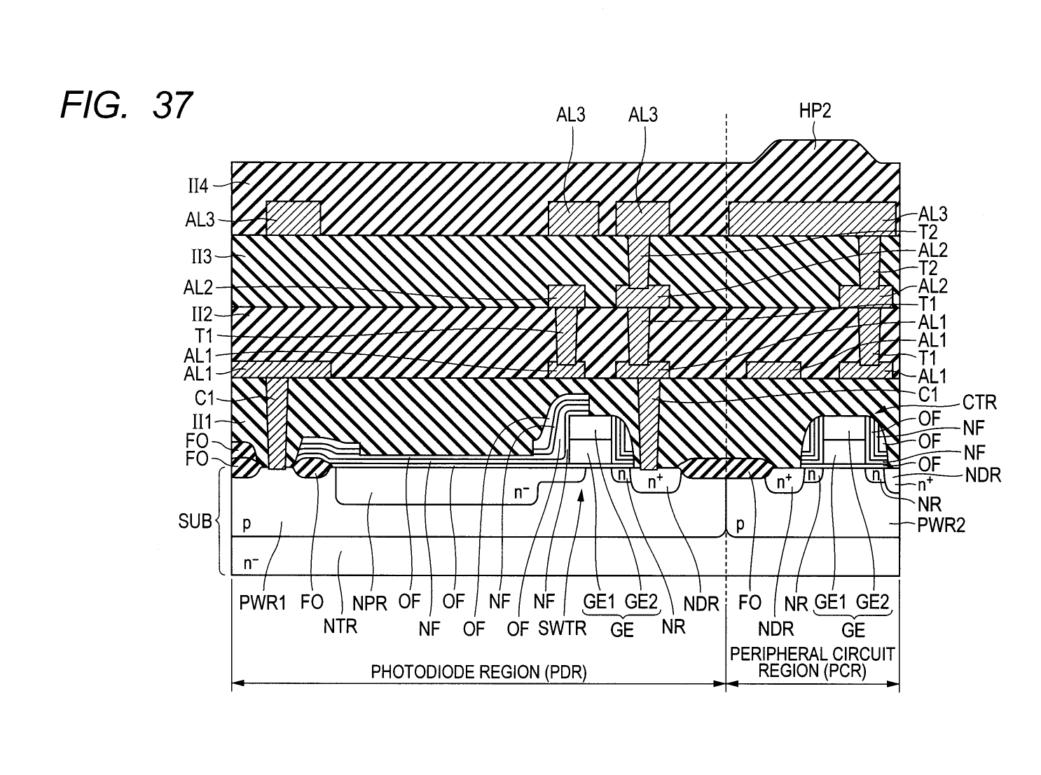

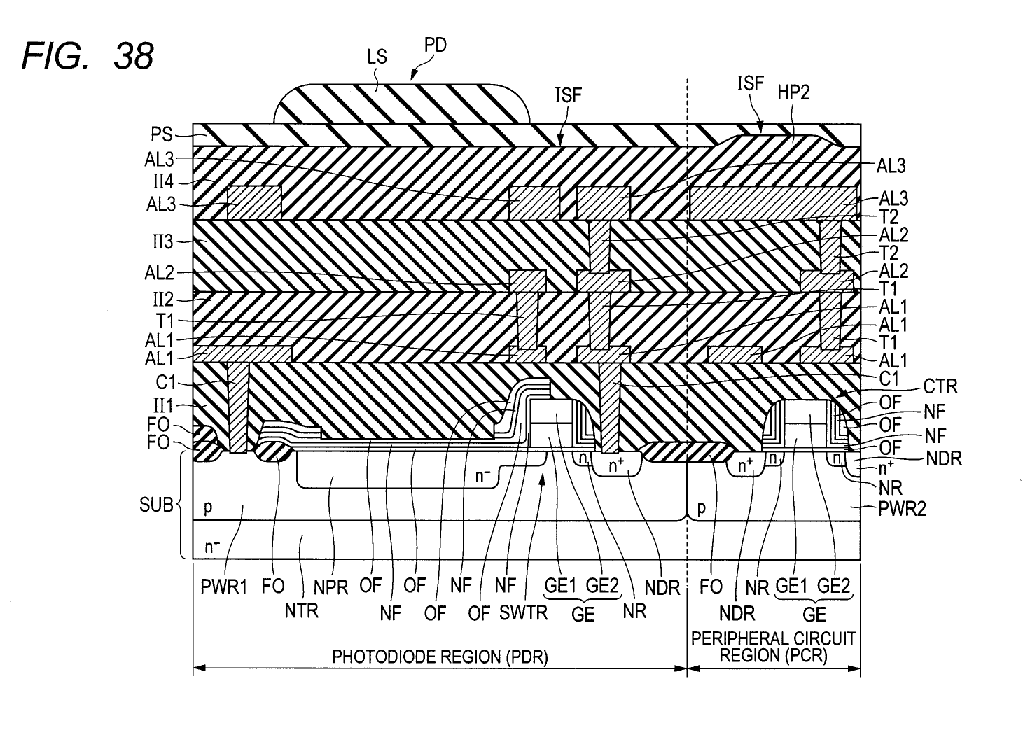

This embodiment is different from the first embodiment in the configuration of the metal wiring AL3. Hereafter, description will be given to the manufacturing method of the semiconductor device (image sensor) in this embodiment with reference to FIG. 37 and FIG. 38.

Also in this embodiment, the steps illustrated in FIG. 8 to FIG. 16 are the same as those in the first embodiment. That is, the thin film AL3 for forming the uppermost-layer wiring is formed.

As illustrated in FIG. 37, the following metal wiring AL3 is formed, especially, in the photodiode region PDR at a step of patterning the thin film AL3 equivalent to FIG. 17: the metal wiring AL3 smaller in width (length of the diagonal lines of each intersecting portion) than the metal wiring AL3 in FIG. 17. After the metal wiring AL3 is formed, the interlayer insulating film II4 is formed as illustrated in FIG. 18 and FIG. 19 related to the first embodiment.

After the step illustrated in FIG. 37 is carried out, the same steps as in FIG. 20 to FIG. 22 are carried out and the image sensor illustrated in FIG. 38 is formed.

Description will be given to the action and effect of this embodiment. As described in relation to the second embodiment, for example, the thickness required for flattening the interlayer insulating film II4 over the metal wiring AL3 is determined by the following: the height and width (length of the diagonal lines of each intersecting portion) of the metal wiring AL3. For this reason, the following can be implemented by making the width of the metal wiring AL3 smaller than the width of the metal wiring AL3 in FIG. 17 as illustrated in FIG. 37: (when the height of the metal wiring AL3 is the same as that in the first embodiment) the interlayer insulating film II4 formed thereover can be flattened even though it is thinner than in the first embodiment.

For this reason, the processing for flattening the interlayer insulating film II4 at a subsequent step as in the second embodiment can be omitted when such a narrow metal wiring AL3 as in FIG. 37 is formed. This can be implemented even in cases where the interlayer insulating film II4 having a thickness of 1300 nm (H+W/4) is formed. This is a thickness with which the uppermost surface of the interlayer insulating film II4 is flattened by slight polishing or etched, for example, in the first embodiment. In this embodiment, for this reason, an image sensor having a thinner laminated structure is formed by a further smaller number of steps.

The sixth embodiment may be carried out by in combination with steps in any of the first embodiment to the fifth embodiment.

The sixth embodiment of the invention is different from the first embodiment of the invention only in the above-mentioned respects. That is, with respect to the sixth embodiment of the invention, the configurations, conditions, procedures, effects, and the like that are not described above are all in accordance with those in the first embodiment of the invention.

The embodiments disclosed here should be considered to be exemplary in every respect and should not be considered to be limitative. The scope of the invention is indicated by WHAT IS CLAIMED IS, not by the above description, and it is intended that it includes every modification within the meaning and scope equivalent to WHAT IS CLAIMED IS.

The invention can be especially advantageously utilized in a semiconductor device including a photoelectric conversion device.

1. A manufacturing method of a semiconductor device, comprising the steps of:
forming in a semiconductor substrate having a main surface a pixel region where a photoelectric conversion element is placed and a peripheral region placed in the peripheral portion of the pixel region in the direction along the main surface;
forming at least one layer of metal wiring over the main surface of the semiconductor substrate;
forming a first interlayer insulating film over the uppermost-layer wiring farthest from the semiconductor substrate among the metal wirings; and
flattening the uppermost surface of the first interlayer insulating film,
wherein the width of the uppermost-layer wiring in the peripheral region along the main surface is larger than the width of the uppermost-layer wiring in the pixel region,
wherein the thickness T, in the direction orthogonal to the main surface, of the first interlayer insulating film formed in an area where the first interlayer insulating film does not overlap with the uppermost-layer wiring as viewed in a plane at the step of forming the first interlayer insulating film meets the relation of T≧H+W/4, where W is the length of the diagonal lines of each intersecting portion of the uppermost-layer wiring placed in the pixel region; and H is the height of the uppermost-layer wiring placed in the pixel region in the direction orthogonal to the main surface, and
wherein after the step of flattening is carried out, the uppermost surface of the first interlayer insulating film in the pixel region is flat and a step is formed in the uppermost surface of the first interlayer insulating film in the peripheral region.

2. The manufacturing method of the semiconductor device according to claim 1,
wherein the first interlayer insulating film is formed by an HDP (high density plasma)-CVD method.

3. The manufacturing method of the semiconductor device according to claim 1,
wherein at the step of flattening, an area equivalent to a certain thickness is etched back from the uppermost surface of the first interlayer insulating film.

4. The manufacturing method of the semiconductor device according to claim 1,
wherein at the step of flattening, an area equivalent to a certain thickness is chemically and mechanically polished from the uppermost surface of the first interlayer insulating film.

5. The manufacturing method of the semiconductor device according to claim 1,
wherein the step of flattening includes the steps of:
forming a second interlayer insulating film comprised of BPTEOS formed by a plasma CVD method so that the second interlayer insulating film is brought into contact with the uppermost surface of the first interlayer insulating film; and
heat treating the first and second interlayer insulating films.

6. The manufacturing method of the semiconductor device according to claim 1,
wherein at the step of flattening, SOG is applied to above the uppermost surface of the first interlayer insulating film.

7. A manufacturing method of a semiconductor device, comprising the steps of:
forming in a semiconductor substrate having a main surface a pixel region where a photoelectric conversion element is placed and a peripheral region placed in the peripheral portion of the pixel region in the direction along the main surface;
forming at least one layer of metal wiring over the main surface of the semiconductor substrate; and
forming a first interlayer, insulating film over the uppermost-layer wiring farthest from the semiconductor substrate among the metal wirings;
wherein the width of the uppermost-layer wiring in the peripheral region along the main surface is larger than the width of the uppermost-layer wiring in the pixel region;
wherein at the step of forming the first interlayer insulating film, the thickness T, in the direction orthogonal to the main surface, of the first interlayer insulating film formed in a area where the first interlayer insulating film does not overlap with the uppermost-layer wiring as viewed in a plane meets the relation of T≧H+W/2, where W is the length of the diagonal lines of each intersecting portion of the uppermost-layer wiring placed in the pixel region; and H is the height of the uppermost-layer wiring placed in the pixel region in the direction orthogonal to the main surface,
wherein after the step of forming the first interlayer insulating film is carried out, the uppermost surface of the first interlayer insulating film in the pixel region is flat and a step is formed in the uppermost surface of the first interlayer insulating film in the peripheral region.

8. The manufacturing method of the semiconductor device according to claim 7,
wherein the first interlayer insulating film is formed by an HDP (high density plasma)-CVD method.

9. A semiconductor device, comprising:
a semiconductor substrate having a main surface;
a pixel region where a photoelectric conversion element is placed, formed in the semiconductor substrate; and
a peripheral region placed in the peripheral portion of the pixel region in the direction along the main surface,
wherein the pixel region and the peripheral region include:
at least one layer of metal wiring formed over the semiconductor substrate; and
a first interlayer insulating film formed over the uppermost-layer wiring farthest from the semiconductor substrate among the metal wirings, and
wherein the uppermost surface of the first interlayer insulating film in the pixel region is flat and a step is formed in the uppermost surface of the first interlayer insulating film in the peripheral region.

10. The semiconductor device according to claim 9,
wherein the thickness T, in the direction orthogonal to the main surface, of the first interlayer insulating film in an area where the first interlayer insulating film does not overlap with the uppermost-layer wiring as viewed in a plane meets the relation of T≧H+W/2, where W is the length of the diagonal lines of each intersecting portion of the uppermost-layer wiring placed in the pixel region along the main surface, and H is the height of the uppermost-layer wiring placed in the pixel region in the direction orthogonal to the main surface.

11. The manufacturing method of the semiconductor device according to claim 2,
wherein at the step of flattening, an area equivalent to a certain thickness is etched back from the uppermost surface of the first interlayer insulating film.

12. The manufacturing method of the semiconductor device according to claim 2,
wherein at the step of flattening, an area equivalent to a certain thickness is chemically and mechanically polished from the uppermost surface of the first interlayer insulating film.

13. The manufacturing method of the semiconductor device according to claim 2,
wherein the step of flattening includes the steps of:
forming a second interlayer insulating film comprised of BPTEOS formed by a plasma CVD method so that the second interlayer insulating film is brought into contact with the uppermost surface of the first interlayer insulating film; and
heat treating the first and second interlayer insulating films.

14. The manufacturing method of the semiconductor device according to claim 2,
wherein at the step of flattening, SOG is applied to above the uppermost surface of the first interlayer insulating film.
